(19) United States
(12) Patent Application Publication
(10) Pub. No.: US 2008/0113295 A1
(43) Pub. Date: May 15, 2008

(54) LIGHT SENSITIVE PRINTING PLATE MATERIAL, PRINTING PLATE AND PROCESS OF PREPARING THE SAME

(76) Inventor: Yasuhiko TAKAMUKI, Tokyo (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/935,934

(22) Filed: Nov. 6, 2007

(30) Foreign Application Priority Data
Nov. 9, 2006 (JP) JP2006-303816

(51) Int. Cl. G03F 7/00

(52) U.S. Cl. 430/270.1; 430/302

(57) ABSTRACT

Disclosed is a process of preparing a printing plate comprising imagewise exposing a light sensitive printing plate material comprising a hydrophilic support and provided thereon, an image formation layer and an oxygen shielding layer in that order, and developing the exposed material with an aqueous solution having a pH of from 3 to 9, wherein the image formation layer contains a photopolymerization initiator (A), a water-soluble polymeric binder (B), a polymerizable ethylenically unsaturated compound (C) and a sensitizing dye (D) represented by formula (1) or (2), and the aqueous solution contains at least one selected from compound A, compound A′, compound B, compound B′ and a compound represented by formula (3),

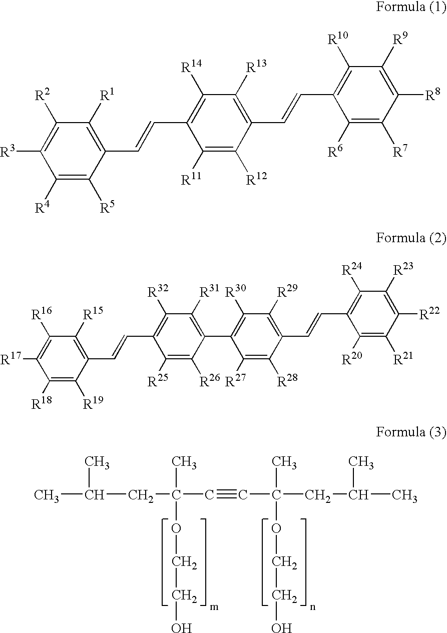

This application is based on Japanese Patent Application No. 2006-303816, filed on Nov. 09, 2006 in Japanese Patent Office, the entire content of which is hereby incorporated by reference.

### FIELD OF THE INVENTION

The present invention relates to a light sensitive printing plate material, a printing plate, and a process of preparing the same.

### BACKGROUND OF THE INVENTION

Generally, a printing plate comprises oleophilic image portions and hydrophilic non-image portions, the former receiving printing ink and the latter receiving dampening water during printing. A printing plate has on the surface image portions as ink receptive portions and hydrophilic non-image portions as dampening water receptive portions (ink repulsive portions), showing difference in ink receptivity between non-image portions and image portions. Printing is carried out employing the difference, wherein printing ink received only by the image portions is transferred onto an image receiving material such as paper.

In order to prepare a printing plate, a light sensitive printing plate material (PS plate) is generally employed which comprises a hydrophilic support and provided thereon, an oleophilic light sensitive layer (image formation layer). Ordinarily, a printing plate is prepared by imagewise exposing the light sensitive printing plate material through an original (such as lithfilm), and developing the exposed material with an alkaline developer or an organic solvent whereby an image formation layer at the image portions remains and an image formation layer at non-image portions is removed to expose the hydrophilic support surface.

In recent years, a digital technique has been developed which image information is electronically processed, stored and output employing a computer. Various novel image output methods employing such a digital technique have been practically used. A computer to plate (CTP) system has been developed, which scanning exposes a light sensitive printing plate material to a highly concentrated light such as laser light based on the digitized image information to obtain directly a printing plate without employing a lith-film. Also in the CTP system, mostly a light sensitive layer at non-image portions after exposure is removed by wet development, in which an aqueous alkaline solution or an organic solvent is employed as a developer.

The plate making process comprises the steps of imagewise exposing a light sensitive printing plate material and developing the material with a developer to remove unnecessary image formation layer. When an alkaline developer or an organic solvent is used as the developer, extra time or cost is necessary for handling of the developer or processing of used developer, or environmental load is increased. Accordingly, it is required to simplify the development and to minimize the environmental load.

As a method of simplifying the development, there is a method employing water or an almost neutral aqueous solution as a developer.

In Japanese Patent O.P.I. Publication No. 2002-365789 is disclosed a processing method of a light sensitive printing plate material comprising the step of exposing a light sensitive printing plate material comprising a hydrophilic support and provided thereon, an image formation layer containing a hydrophobic material precursor, a hydrophilic resin, a light-to-heat conversion material and a compound having a polyethyleneoxy chain, and developing the exposed material with water or an appropriated aqueous solution as a developer to obtain a printing plate for printing.

In US Patent Publication No. 2004-0013968 is disclosed a processing method of a light sensitive printing plate material comprising the step of exposing to infrared laser a light sensitive printing plate material comprising a hydrophilic support and provided thereon, an oleophilic thermosensitive layer containing a radical polymerizable ethylenically unsaturated monomer and a radical polymerization initiator and an infrared absorbing dye, and developing the exposed material with an aqueous developer with a pH of from 2.0 to 10.0 containing 60% by weight or more of water to remove the thermosensitive layer at non-image portions.

The processing method of a light sensitive printing plate material comprising the step of exposing a light sensitive printing plate material comprising an image formation layer containing a compound having a polyethyleneoxy chain, and developing the exposed material with water or an appropriated aqueous solution is disclosed in Japanese Patent O.P.I. Publication No. 2002-365789. However, a light sensitive printing plate material containing the compound having a polyethyleneoxy chain as disclosed in this patent has problem in that the components in the image formation layer are incorporated into the developer, whereby the developer is rapidly fatigued resulting in background contamination.

Hitherto, a conventional light sensitive printing plate material is developed with an alkaline developer with a pH of 12.0 or more. In contrast, use of a light sensitive printing plate material capable of being developed with an aqueous developer with a pH of from 2.0 to 10.0 is disclosed in US Patent Publication No. 2004-0013968. However, a light sensitive printing plate material containing the sensitizing dye as disclosed in this patent has problems in that sensitivity and printing durability are low.

### SUMMARY OF THE INVENTION

An object of the invention is to provide a light sensitive printing plate material and a printing plate providing high sensitivity and high printing durability. Another object of the invention is to provide a process of preparing a printing plate in which background contamination due to a fatigue developer is minimized and environmental load regarding development is minimized.

### BRIEF DESCRIPTION OF THE DRAWINGS

FIG. 1 shows one embodiment of an automatic developing machine used in the invention.

FIG. 2 shows one embodiment of a developing section of an automatic developing machine used in the invention.

### DETAILED DESCRIPTION OF THE INVENTION

The above object has been attained by one of the following constitutions:

1. A process of preparing a printing plate comprising the steps of (a) imagewise exposing a light sensitive printing plate material comprising a hydrophilic support and provided thereon, an image formation layer and an oxygen shielding layer in that order, and (b) developing the exposed light sensitive printing plate material with an aqueous solution having a pH of from 3 to 9 to remove an image formation layer at unexposed portions,

wherein the image formation layer contains a photopolymerization initiator (A), a water-soluble polymeric binder (B), a polymerizable ethylenically unsaturated compound (C) and a sensitizing dye (D) represented by formula (1) or (2),

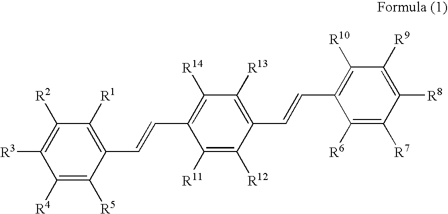

wherein R¹, R², R³, R⁴, R⁵, R⁶, R⁷, R⁸, R⁹, R¹⁰, R¹¹, R¹², R¹³ and R¹⁴ independently represent a hydrogen atom, an alkyl group, an alkoxy group, a cyano group or a halogen atom, provided that at least one of R¹, R², R³, R⁴, R⁵, R⁶, R⁷, R⁸, R⁹ and R¹⁰ represents an alkoxy group having a carbon atom number of not less than 1,

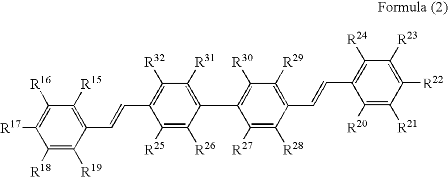

wherein R¹⁵, R¹⁶, R¹⁷, R ¹⁸, R¹⁹, R²⁰, R²¹ , R²², R²³, R²⁴, R²⁵, R²⁶, R²⁷, R²⁸, R²⁹, R³⁰, R³¹ and R³² independently represent a hydrogen atom, an alkyl group, an alkoxy group, a cyano group or a halogen atom, provided that at least one of R¹⁵, R¹⁶, R¹⁷, R¹⁸, R¹⁹, R²⁰, R²¹, R²², R²³ and R²⁴ represents an alkoxy group having a carbon atom number of not less than 1, and

wherein the aqueous solution contains at least one selected from compound A, compound A′, compound B, compound B′ and a compound represented by formula (3), the compound A being a nonionic surfactant having in the molecule a first hydrophobic group containing no saturated hydrocarbon group, the compound A′ being a nonionic surfactant having in the molecule a second hydrophobic group containing a saturated hydrocarbon group in which the molecular weight ratio of the saturated hydrocarbon group to the second hydrophobic group is from more than 0 to 25%, the compound B being an anionic surfactant having in the molecule a third hydrophobic group containing no saturated hydrocarbon group, and the compound B′ being an anionic surfactant having in the molecule a fourth hydrophobic group containing a saturated hydrocarbon group in which the molecular weight ratio of the saturated hydrocarbon group to the second hydrophobic group is from more than 0 to 25%,

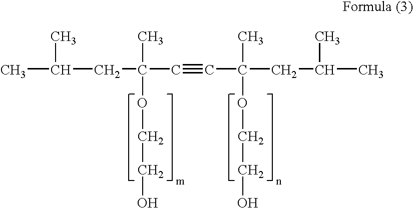

wherein m and n independently represent an integer of 1 or more.

2. The process of item 1 above, further comprising, between the exposing and developing steps, the steps of preheating the exposed light sensitive planographic printing plate material, and pre-washing the preheated material with the aqueous solution.

3. The process of item 1 above, wherein the exposing is carried out employing a laser.

4. The process of item 1 above, wherein the image formation layer further comprises copper-free phthalocyanine as a colorant.

5. A light sensitive printing plate material comprising a hydrophilic support and provided thereon, an image formation layer and an oxygen shielding layer in that order, wherein the image formation layer contains a photopolymerization initiator (A), a water soluble polymeric binder (B), a polymerizable ethylenically unsaturated compound (C) and a sensitizing dye (D) represented by formula (1) or (2),

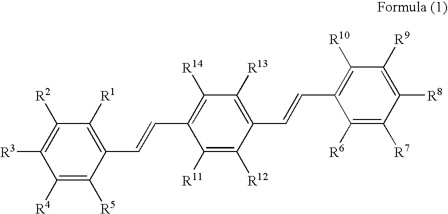

wherein R¹, R², R³, R⁴, R⁵, R⁶, R⁷, R⁸, R⁹, R¹⁰, R¹¹, R¹², R¹³ and R¹⁴ independently represent a hydrogen atom, an alkyl group, an alkoxy group, a cyano group or a halogen atom, provided that at least one of R¹, R², R³, R⁴, R⁵, R⁶, R⁷, R⁸, R⁹ and R¹⁰ represents an alkoxy group having a carbon atom number of not less than 1,

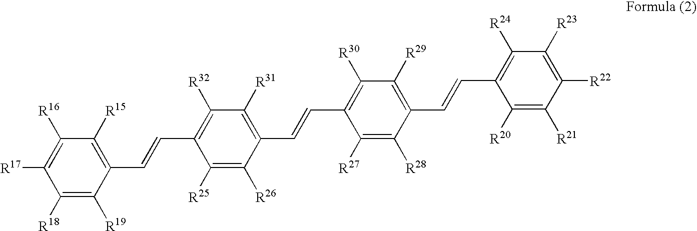

wherein R¹⁵, R¹⁶ , R¹⁷, R¹⁸, R¹⁹, R²⁰, R²¹, R²², R²³, R²⁴, R²⁵, R²⁶, R²⁷, R²⁸ , R²⁹, R³⁰, R³¹ and R³² independently represent a hydrogen atom, an alkyl group, an alkoxy group, a cyano group or a halogen atom, provided that at least one of R¹⁵, R¹⁶, R¹⁷, R¹⁸, R¹⁹, R²¹, R²², R²³ and R²⁴ represents an alkoxy group having a carbon atom number of not less than 1.

6. The light sensitive printing plate material of item 5 above, wherein the image formation layer further comprises copper-free phthalocyanine as a colorant.

The present inventor has made an extensive study in view of the above. As a result, the inventor has found that a process of preparing a printing plate can attain the above object which comprises the steps of imagewise exposing a light sensitive printing plate material comprising a hydrophilic support and provided thereon, an image formation layer and an oxygen shielding layer in that order, developing the exposed light sensitive printing plate material with an aqueous solution having a pH of from 3 to 9 to remove unexposed portions, wherein the image formation layer contains a photopolymerization initiator (A), a water soluble polymeric binder (B), a polymerizable ethylenically unsaturated compound (C) and a sensitizing dye (D) having a specific structure and the aqueous solution contains a surfactant having a specific structure, and has completed the invention.

The present invention will be explained in detail below.

### [Light Sensitive Printing Plate Material]

The light sensitive printing plate material used in the invention is characterized in that it comprises a hydrophilic support and provided thereon, an image formation layer and an oxygen shielding layer in that order, wherein the image formation layer contains a photopolymerization initiator (A), a water soluble polymeric binder (B), a polymerizable ethylenically unsaturated compound (C) and a sensitizing dye (D) represented by formula (1) or (2).

### <<Support>>

The support used in the invention is a plate or a sheet capable of carrying an image formation layer and preferably has a hydrophilic surface on the side on which the image formation layer is to be provided.

As the supports used in the invention, a plate of a metal such as aluminum, stainless steel, chromium or nickel, or a plastic film such as a polyester film, a polyethylene film or a polypropylene film, which is deposited or laminated with the above-described metal can be used.

Further, a polyester film, a polyvinyl chloride film or a nylon film whose surface is subjected to hydrophilization treatment can be used. In the invention, an aluminum support is preferably used in view of printing durability, and an aluminum palate subjected to anodization treatment as described later is especially preferably used.

As a plate for an aluminum support, a pure aluminum plate or an aluminum alloy plate is used.

As the aluminum alloy, there can be used various ones including an alloy of aluminum and a metal such as silicon, copper, manganese, magnesium, chromium, zinc, lead, bismuth, nickel, titanium, sodium or iron. In the aluminum plate for the support, the surface is roughened for water retention.

It is preferable that the aluminum plate is subjected to degreasing treatment for removing rolling oil prior to surface roughening (graining). The degreasing treatments include degreasing treatment employing solvents such as trichlene and thinner, and an emulsion degreasing treatment employing an emulsion such as kerosene or triethanol. It is also possible to use an aqueous alkali solution such as caustic soda for the degreasing treatment. When an aqueous alkali solution such as caustic soda is used for the degreasing treatment, it is possible to remove soils and an oxidized film which can not be removed by the above-mentioned degreasing treatment alone. When an aqueous alkali solution such as caustic soda is used for the degreasing treatment, the resulting support is preferably subjected to desmut treatment in an aqueous solution of an acid such as phosphoric acid, nitric acid, sulfuric acid, chromic acid, or a mixture thereof, since smut is produced on the surface of the support. The surface roughening methods include a mechanical surface roughening method and an electrolytic surface roughening method electrolytically etching the support surface.

Though there is no restriction for the mechanical surface roughening method, a brushing roughening method and a honing roughening method are preferable.

Though there is no restriction for the electrolytic surface roughening method, a method, in which the support is electrolytically surface roughened in an acidic electrolytic solution, is preferred.

After the support has been electrolytically surface roughened, it is preferably dipped in an acid or an aqueous alkali solution in order to remove aluminum dust, etc. produced in the surface of the support. Examples of the acid include sulfuric acid, persulfuric acid, hydrofluoric acid, phosphoric acid, nitric acid and hydrochloric acid, and examples of the alkali include sodium hydroxide and potassium hydroxide. Among those mentioned above, the aqueous alkali solution is preferably used. The dissolution amount of aluminum in the support surface is preferably 0.5 to 5 g/m². After the support has been dipped in the aqueous alkali solution, it is preferable for the support to be dipped in an acid such as phosphoric acid, nitric acid, sulfuric acid and chromic acid, or in a mixed acid thereof, for neutralization.

The mechanical surface roughening and electrolytic surface roughening may be carried out singly, and the mechanical surface roughening followed by the electrolytic surface roughening may be carried out.

After the surface roughening, anodizing treatment may be carried out. There is no restriction in particular for the method of anodizing treatment used in the invention, and known methods can be used. The anodizing treatment forms an anodization film on the surface of the support.

The support which has been subjected to anodizing treatment is optionally subjected to sealing treatment. For the sealing treatment, it is possible to use known methods using hot water, boiling water, steam, a sodium silicate solution, an aqueous dichromate solution, a nitrite solution and an ammonium acetate solution.

After the above treatment, the support is suitably undercoated with a water soluble resin such as polyvinyl phosphonic acid, a polymer or copolymer having a sulfonic acid in the side chain, or polyacrylic acid; a water soluble metal salt such as zinc borate; a yellow dye; an amine salt; and so on, for hydrophilization treatment. The sol-gel treatment support disclosed in Japanese Patent O.P.I. Publication No. 5-304358, which has a functional group capable of causing addition reaction by radicals as a covalent bond, is suitably used.

### <<Image Formation Layer>>

In the invention, the image formation layer contains a photopolymerization initiator (A), a water soluble polymeric binder (B), a polymerizable ethylenically unsaturated compound (C) and a sensitizing dye (D) represented by formula (1) or (2).

### (Photopolymerization Initiator)

The photopolymerization initiator in the invention is a compound which initiates polymerization of an ethylenically unsaturated compound on light exposure. As the photopolymerization initiator is preferably used a titanocene compound, a monoalkyltriaryl borate compound, an iron arene complex or a polyhalogenated compound. Among these, an iron arene complex or a polyhalogenated compound is more preferred in view of handling property under yellow lamp.

As the titanocene compounds, there are those described in Japanese Patent O.P.I. Publication Nos. 63-41483 and 2-291. Preferred examples of titanocene compounds include bis(cyclopentadienyl)-Ti-di-chloride, bis(cyclopentadienyl)-Ti-bis-phenyl, bis(cyclopentadienyl)-Ti-bis-2,3,4,5,6-pentaflurophenyl, bis(cyclopentadienyl)-Ti-bis-2,3,5,6-tetrafluorophenyl, bis(cyclopentadienyl)-Ti-bis-2,4,6-trifluorophenyl, bis(cyclopentadienyl)-Ti-bis-2,6-difluorophenyl, bis(cyclopentadienyl)-Ti-bis-2,4-difluorophenyl, bis(methylcyclopentadienyl)-Ti-bis-2,3,4,5,6-pentafluorophenyl, bis(methylcyclopentadienyl)-Ti-bis-2,3,5,6-tetrafluorophenyl, bis(methylcyclopentadienyl)-Ti-bis-2,6-difluorophenyl (IRUGACURE 784, produced by Ciba Speciality Chemicals Co.), bis(cyclopentadienyl)-bis(2,4,6-trifluoro-3-(pyry-1-yl)phenyl)titanium, and bis(cyclopentadienyl)-bis(2,4,6-trifluoro-3-(2-5-dimethylpyry-1-yl)phenyl)titanium.

As the monoalkyltriaryl borate compounds, there are those described in Japanese Patent O.P.I. Publication Nos. 62-150242 and 62-143044. Preferred examples of the monoalkyl-triaryl borate compounds include tetra-n-butyl ammonium n-butyl-trinaphthalene-1-yl-borate, tetra-n-butyl ammonium n-butyl-triphenyl-borate, tetra-n-butyl ammonium n-butyl-tri-(4-tert-butylphenyl)-borate, tetra-n-butyl ammonium n-hexyl-tri-(3-chloro-4-methylphenyl)-borate, and tetra-n-butyl ammonium n-hexyl-tri-(3-fluorophenyl)-borate.

As the iron-arene complexes, there are those disclosed in Japanese Patent O.P.I. Publication No. 59-219307.

Preferred examples of the iron-arene complex include η-benzene-(η-cyclopentadienyl)iron hexafluorophosphate, η-cumene-(η-cyclopentadienyl)iron hexafluorophosphate, η-fluorene-(η-cyclopentadienyl)iron hexafluorophosphate, η-naphthalene-η-cyclopentadienyl)iron hexafluorophosphate, η-xylene-η-cyclopentadienyl)iron hexafluorophosphate, and η-benzene-η-cyclopentadienyl)iron tetrafluorophosphate.

The polyhalogenated compound is a compound having a trihalomethyl group, a dihalomethyl group or a dihalomethylene group. Examples thereof include an oxadiazole compound having in the oxadiazole ring the group described above as the substituent or a polyhalogenated compound represented by the following formula (4) is preferably used.

R¹—C (Y)₂—(C═O)—R² Formula (4)

wherein R′ represents a hydrogen atom, a halogen atom, an alkyl group, an aryl group, an acyl group, an alkylsulfonyl group, an arylsulfonyl group, an iminosulfo group or a cyano group; R² represents a monovalent substituent, provided that R¹ and R² may combine with each other to form a ring; and Y represents a halogen atom.

Examples of the compound represented by formula (4) include BR1 through BR66 listed below. In the invention, compounds can be suitably used in which the bromine atoms in these examples are replaced with chlorine atoms.

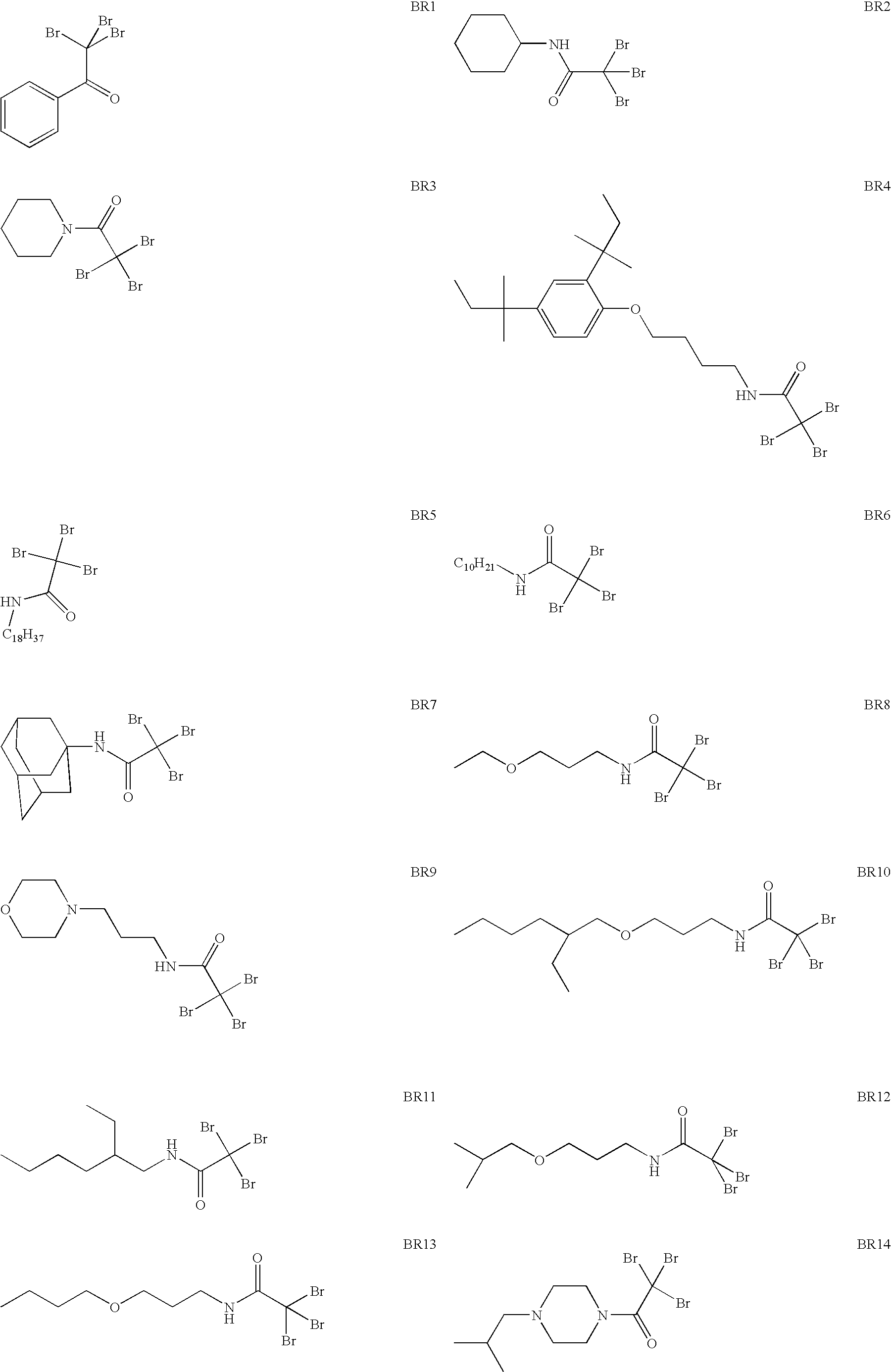

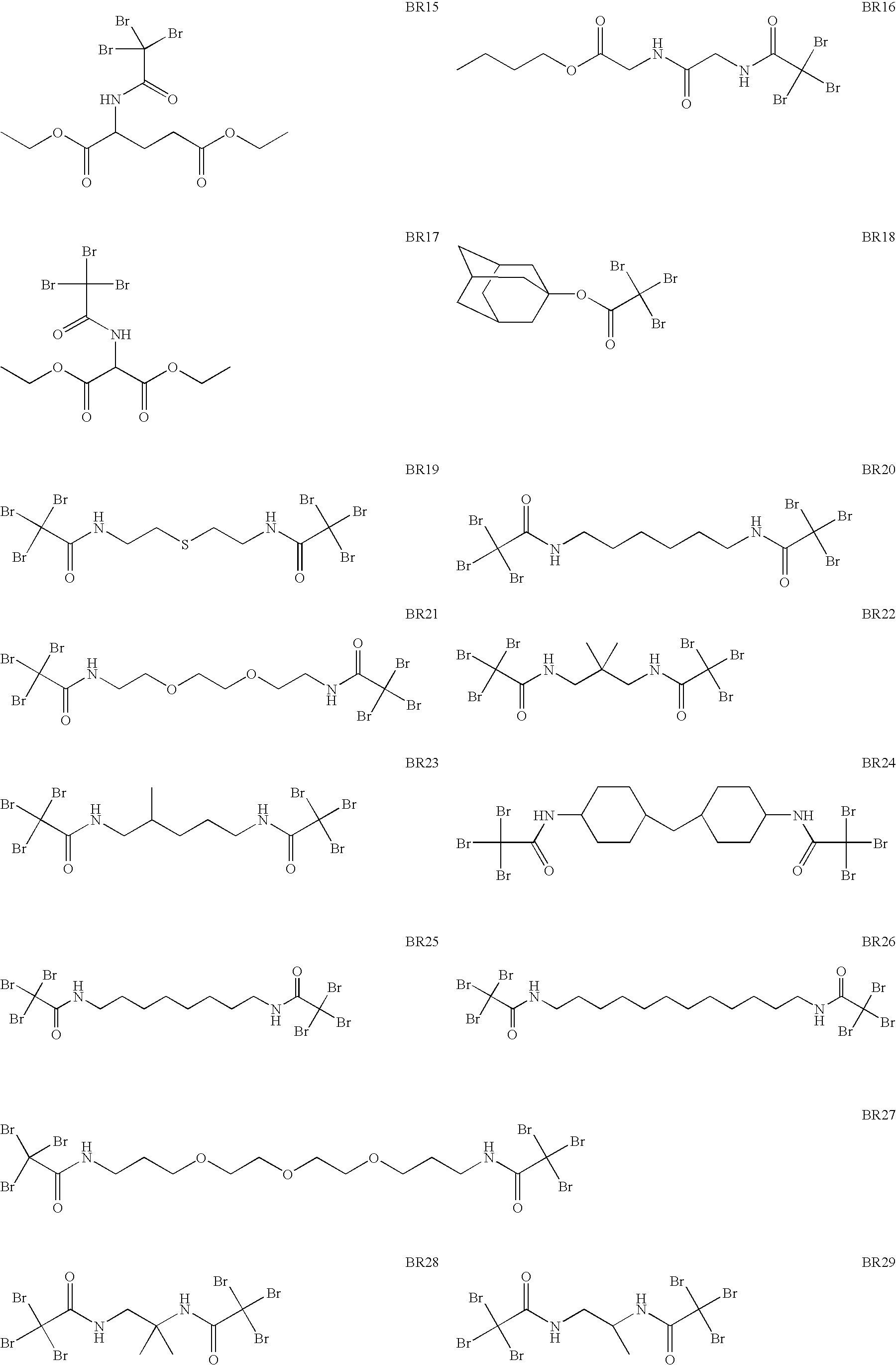

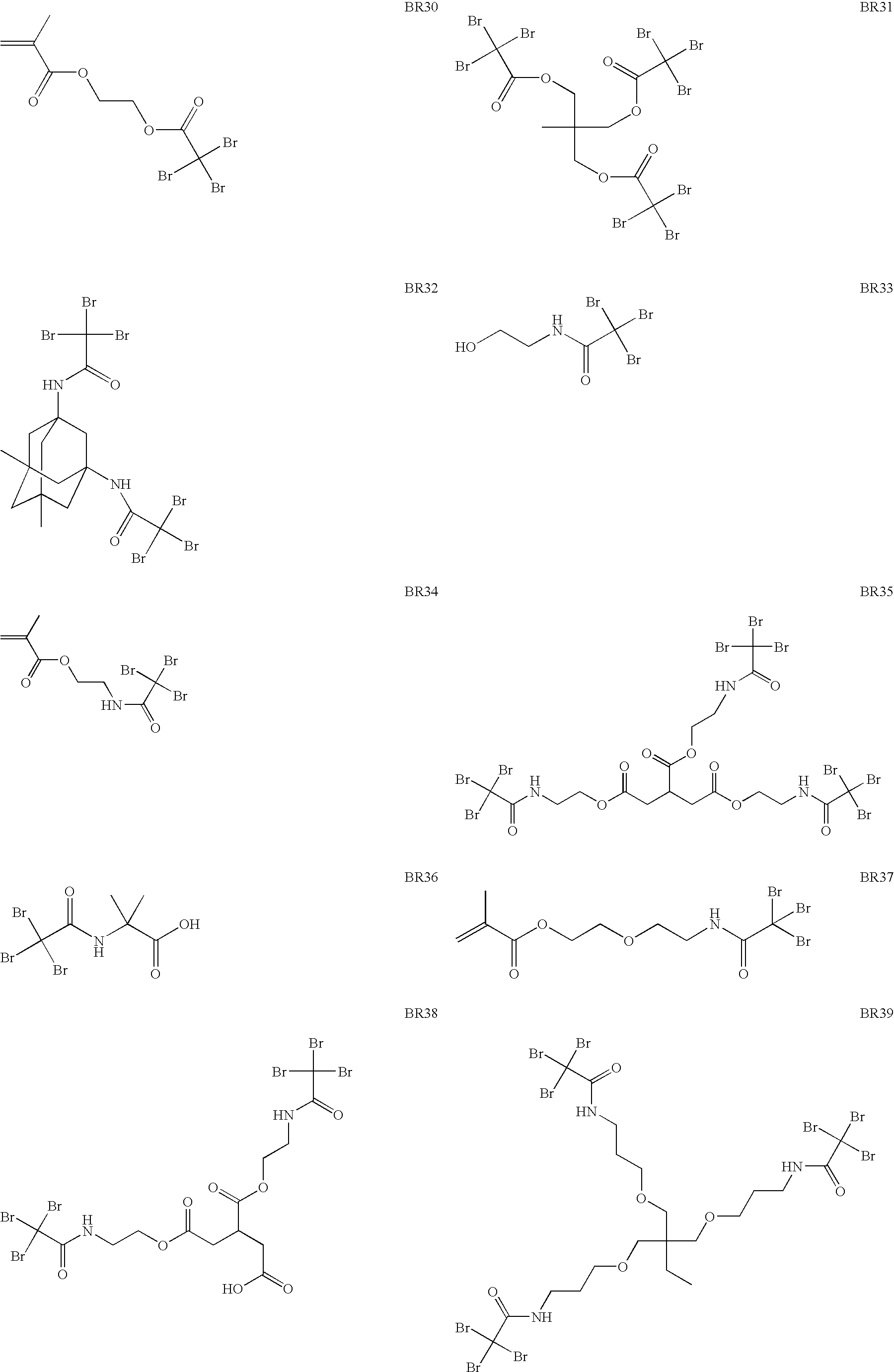

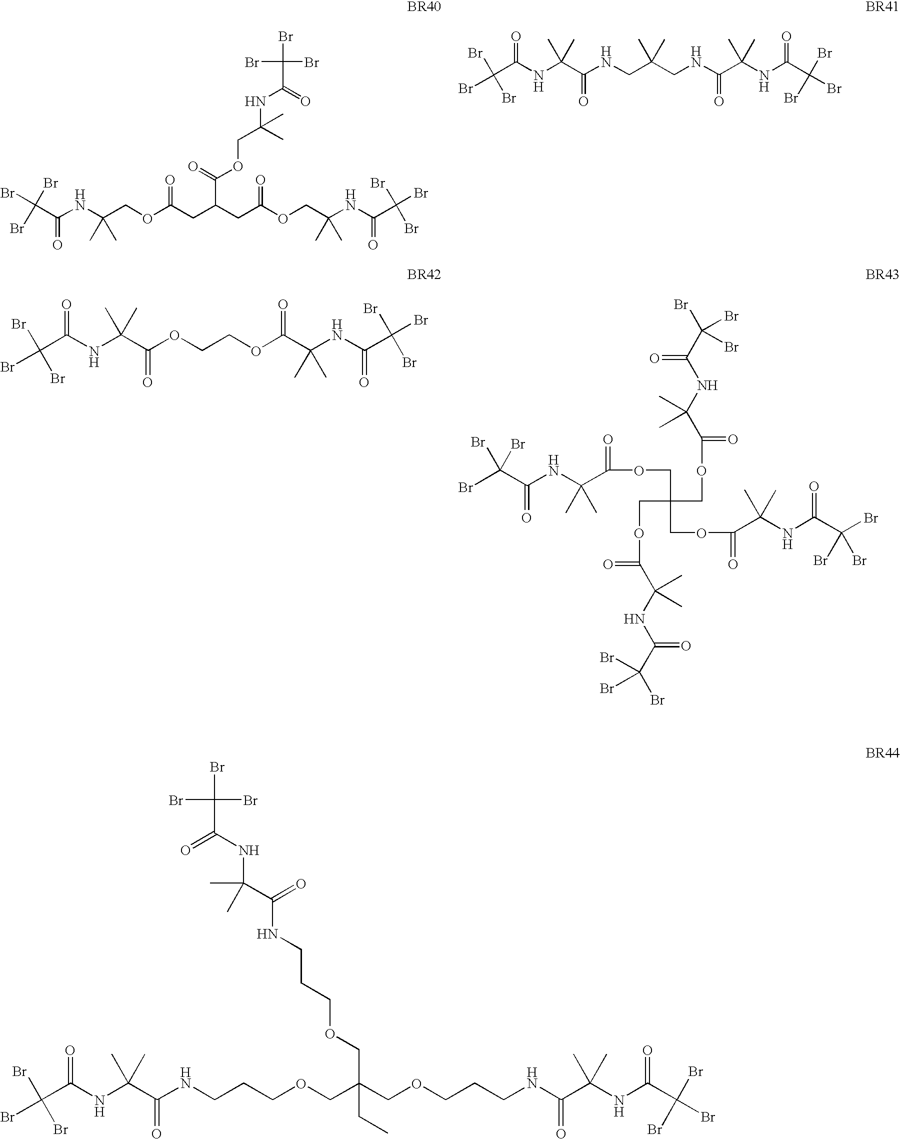

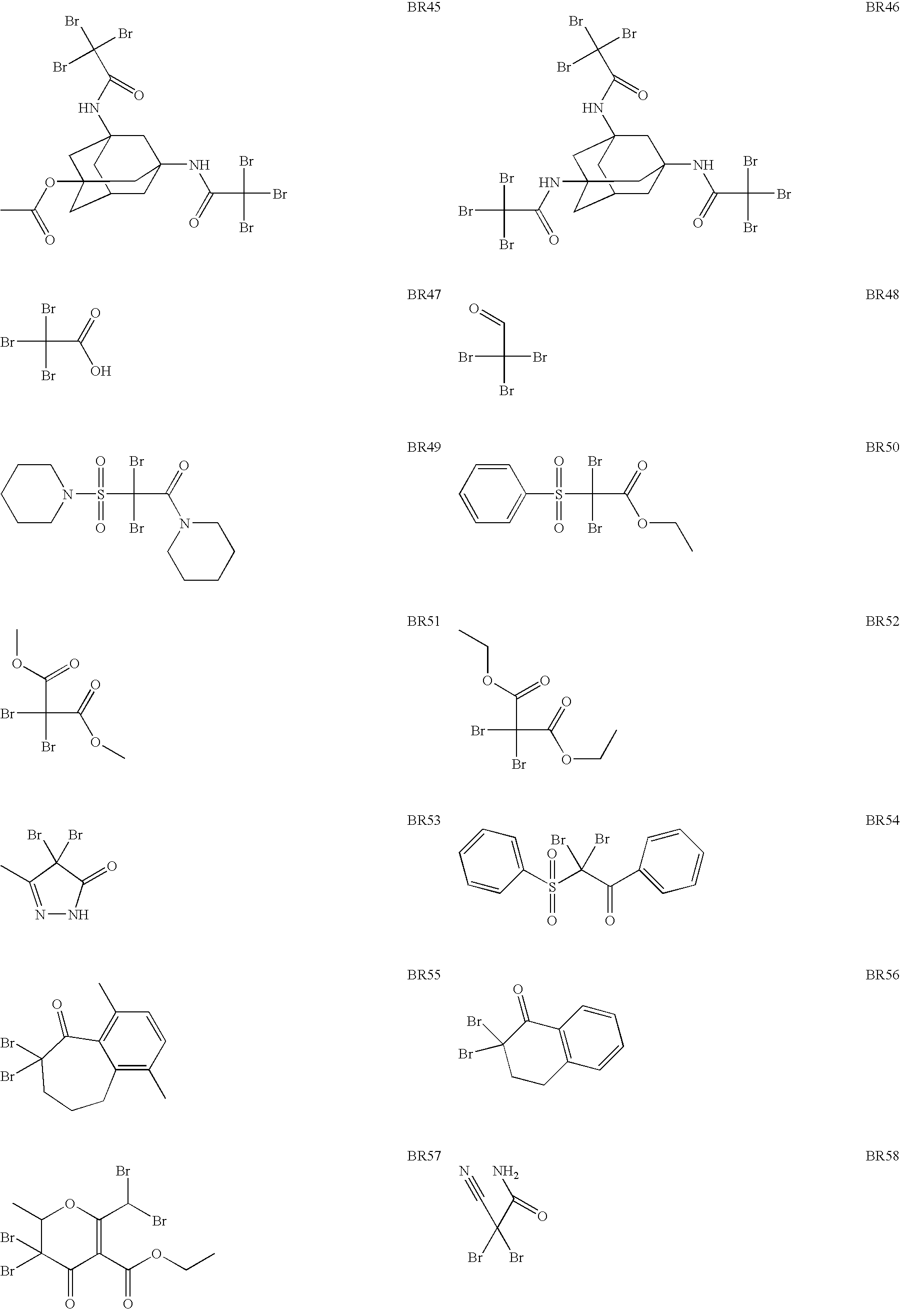

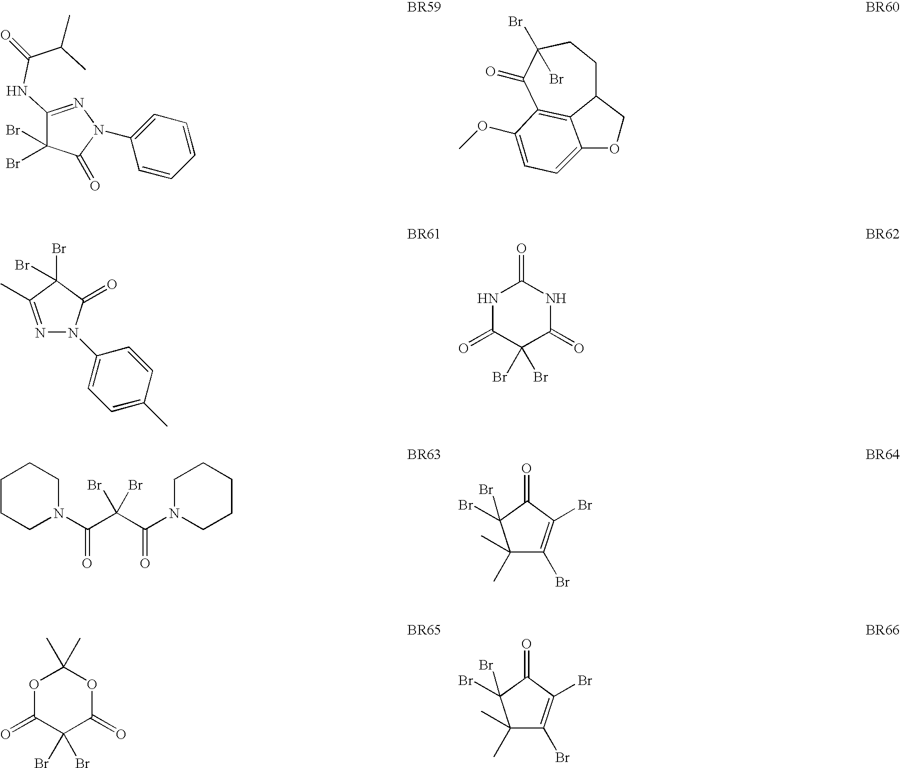

Another photopolymerization initiator can be used in combination. Examples thereof include carbonyl compounds, organic sulfur compounds, peroxides, redox compounds, azo or diazo compounds, hakides and photo-reducing dyes disclosed in J. Kosar “Light Sensitive Systems”, paragraph 5, and those disclosed in British Patent No. 1,459,563.

Typical examples of the photopolymerization initiator used in combination include the following compounds:

A benzoin derivative such as benzoin methyl ether, benzoin i-propyl ether, or α,α-dimethoxy-α-phenylacetophenone; phenylacetophenone; a benzophenone derivative such as benzophenone, 2,4-dichlorobenzophenone, o-benzoyl methyl benzoate, or 4,4′-bis (dimethylamino) benzophenone; a thioxanthone derivative such as 2-chlorothioxanthone, 2-i-propylthioxanthone; an anthraquinone derivative such as 2-chloroanthraquinone or 2-methylanthraquinone; an acridone derivative such as N-methylacridone or N-butylacridone; α,α-diethoxyacetophenone; benzil; fluorenone; xanthone; an uranyl compound; a triazine derivative disclosed in Japanese Patent Publication Nos. 59-1281 and 61-9621 and Japanese Patent O.P.I. Publication No. 60-60104; an organic peroxide compound disclosed in Japanese Patent O.P.I. Publication Nos. 59-1504 and 61-243807; a diazonium compound in Japanese Patent Publication Nos. 43-23684, 44-6413, 47-1604 and US Patent No. 3,567,453; an organic azide compound disclosed in US Patent Nos. 2,848,328, 2,852,379 and 2,940,853; orthoquinonediazide compounds disclosed in Japanese Patent Publication Nos. 36-22062b, 37-13109, 38-18015 and 45-9610; various onium compounds disclosed in Japanese Patent Publication No. 55-39162, Japanese Patent O.P.I. Publication No. 59-14023 and “Macromolecules”, Volume 10, p. 1307 (1977); azo compounds disclosed in Japanese Patent Publication No. 59-142205; metal arene complexes disclosed in Japanese Patent O.P.I. Publication No. 1-54440, European Patent Nos. 109,851 and 126,712, and “Journal of Imaging Science”, Volume 30, p. 174 (1986); (oxo) sulfonium organoboron complexes disclosed in Japanese Patent O.P.I. Publication Nos. 5-213861 and 5-255347; titanocenes disclosed in Japanese Patent O.P.I. Publication Nos. 59-152396 and 61-151197; transition metal complexes containing a transition metal such as ruthenium disclosed in “Coordination Chemistry Review”, Volume 84, p. 85-277 (1988) and Japanese Patent O.P.I. Publication No. 2-182701; 2,4,5-triarylimidazol dimmer disclosed in Japanese Patent O.P.I. Publication No. 3-209477; carbon tetrabromide; organic halide compounds disclosed in Japanese Patent O.P.I. Publication No. 59-107344.

The content of the photopolymerization initiator in the image formation layer is preferably from 0.1 to 20% by weight, and more preferably from 0.5 to 15% by weight, based on a polymerizable ethylenically unsaturated compound contained in the image formation layer.

### (Water-Soluble Polymeric Binder)

The water-soluble polymeric binder in the invention is one capable of carrying photopolymerization initiator (A), a polymerizable ethylenically unsaturated compound (C), and a sensitizing dye represented by formula (1) or (2), each being a component contained in the image formation layer.

The water-soluble polymeric binder in the invention means a compound having a water solubility of at least 0.1 and a molecular weight (weight average molecular weight) of at least 500. Herein, the water solubility is specified by the saturation concentration (grams) of a solute soluble in 100 g of 25 ° C. water.

Examples of the water-soluble polymeric binder in the invention include polyvinyl alcohol, a homopolymer or copolymer of hydroxystyrene, a polyamide resin, a homopolymer or copolymer of vinyl pyrrolidone, polyethylene oxide, polyethylene imine, polyacrylamide, corn starch, mannan, pectin, agar, dextran, pullulan, glue, hydroxymethyl-cellulose, alginic acid, carboxymethylcellulose, and sodium polyacrylate.

Specifically, a polymeric compound having a nonionic hydrophilic group is preferably used as the water-soluble polymeric binder in the invention.

The polymeric binder has an weight average molecular weight of preferably from 1,000 to 100,000, and more preferably from 1,000 to 50,000, in view of printing durability and image reproduction.

The image formation layer in the invention may contain a compound other than the water-soluble polymeric binder in the invention as a binder, but the content of the water-soluble polymeric binder in the invention is preferably from 80 to 100% by weight, and more preferably from 90 to 100% by weight, based on the total weight of the binder.

The binder content of the image formation layer in the invention is preferably from 10 to 95% by weight, and more preferably from 30 to 90% by weight, based on the weight of image formation layer.

Examples of the binder used in combination include a polyvinyl butyral resin, a polyester resin, an epoxy resin, a phenol resin, a polycarbonate resin, a polyvinyl formal resin, shellac and other natural resins.

### (Polymeric Compound having Nonionic Hydrophilic Group)

The nonionic hydrophilic group contained in the polymeric compound described above having a nonionic hydrophilic group means a group or bond exhibiting hydrophilicity without being ionized in water, and examples thereof include an alcoholic hydroxyl group, an aromatic hydroxyl group, an acid amide group, a sulfonamide group, a thiol group, a pyrrolidone group, a polyoxyethylene group, a polyoxypropylene group, a sugar residue and so forth.

As the polymeric compound having a nonionic hydrophilic group, a compound containing a nonionic hydrophilic group of at least 30% by weight is preferred in view of developability.

The polymeric compound containing the above-described nonionic hydrophilic group is preferably an oligomer or a polymer having a weight average molecular weight of from 1,000 to 50,000, in view of developability and image reproduction, and examples thereof include a polymer obtained by polymerizing at least one unsaturated monomer having the foregoing nonionic hydrophilic group in the side chain, a polyvinyl alcohol based polymer, and a cellulose based polymer as polysaccharide, and a glucose based polymer Examples of the unsaturated monomer having an amide group in the side chain include unsubstituted or substituted (meth)acrylamide; an amidated monomer of a dibasic acid such as an itaconic acid, a fumaric acid or a maleic acid; N-vinylacetoamide; N-vinylformamide; N-vinylpyrrolidone and so forth.

Typical examples of unsubstituted or substituted (meth)acrylamide include (meth)acrylamide, N-methyl(meth)acrylamide, N,N-dimethyl(meth)acrylamide, N-ethyl(meth)acrylamide, N,N-diethyl(meth)acrylamide, N,N-dimethylaminopropyl(meth)acrylamide, N-isopropyl(meth)acrylamide, diacetone(meth)acrylamide, methylol(meth)acrylamide, methoxymethyl(meth)acrylamide, butoxymethyl(meth)acrylamide, sulfonic acid propyl(meth)acrylamide and (meth)acryloylmorpholine.

The amidated monomer of a dibasic acid such as the foregoing itaconic acid and so forth may be a monomide in which one carboxyl group is amidated, a diamide in which both carboxyl groups are amidated, or an amideester in which one carboxyl group is amidated, and the other carboxyl group is esterified.

Examples of the unsaturated monomer having a hydroxyl group include hydroxyethyl(meth)acrylate, hydroxypropyl(meth)acrylate, hydroxybutyl(meth)acrylate, a monomer in which ethyleneoxide or propyleneoxide is added thereto, methylol(meth)acrylamide, and methoxymethyl(meth)acrylamide and butoxymethyl-(meth)acrylamide, which are a condensation product of the methylol(meth)acrylamide with methyl alcohol or butyl alcohol.

The foregoing “(meth)acryl”, “(meth)acrylate” and “(meth)acryloyl” mean acryl or methacryl, acrylate or meth acrylate, and acryloyl or methacryloyl, respectively.

A polyvinyl alcohol based polymer will further be described in detail. Examples thereof include a polymer obtained via complete or partial hydrolysis of a homopolymer or a copolymer of a fatty acid vinyl monomer such as vinyl acetate or vinyl propionate, and a polymer obtained by partial formalization, acetalization or butyralization of the foregoing polymer.

The polymeric compound containing a nonionic hydrophilic group of at least 30% by weight may possess a crosslinking functional group reacting with a crosslinking agent. The crosslinking functional group is preferably a nonionic one, depending on kinds of the crosslinking agent, and examples thereof include a hydroxyl group, an isocyanate group, a glycidyl group, an oxazolyl group and so forth.

In order to introduce these crosslinking functional groups, an unsaturated monomer having the functional group such as a unsaturated monomer having the foregoing hydroxyl group or glycidyl(meth)acrylate as a unsaturated monomer having the glycidyl group may be copolymerized with another (meth)acrylate monomer.

A polymeric compound containing a nonionic hydrophilic group of 30% by weight may be a compound obtained by copolymerization of an unsaturated monomer having the foregoing nonionic hydrophilic group and an unsaturated monomer having a crosslinking functional group with another unsaturated co-monomer in order to further produce the effect of the present invention.

Examples of another unsaturated comonomer include methyl(meth)acrylate, ethyl(meth)acrylate, butyl(meth)acrylate, 2-ethylhexyl(meth)acrylate, glycidyl(meth)acrylate, methoxy(C1-C50)ethyleneglycol (meth)acrylate, dimethylaminoethyl (meth)acrylate, diethylaminoethyl (meth)acrylate, phenoxyethyl (meth)acrylate, benzyl (meth)acrylate, isopronyl (meth)acrylate, adamantly (meth)acrylate, cyclohexyl (meth)acrylate, styrene, α-methylstyrene, acrylonitrile, methacrylonitrile, vinyl acetate and a-olefin (C4-C30).

As a crosslinking agent used for crosslinking the polymeric compound containing a nonionic hydrophilic group of at least 30% by weight, a combination of the crosslinking agents and the functional group as used in reaction described in “Crosslinking agent Handbook” (edited by T. Kaneko and S. Yamashita and published in 1981 by Taisei Co., Ltd.) can be selected.

Examples of the crosslinking agent include polyhydric alcohols, polycarboxylic acids and their anhydrides, polyglycidyl compounds (epoxy resins), polyamine compounds, polyamide resins, polyisocyanate compounds (including blocked isocianates), oxazoline resins; amino resins, and glyoxals, which are capable of reacting with a hydroxyl group, a glycidyl group or opitionally an amido group as a crosslinking functional group in a polymeric compound containing a nonionic hydrophilic group of at least 30% by weight.

Among the foregoing crosslinking agents, commonly known various glycidyl compounds (epoxy resins), a hardener for an epoxy resin such as oxazoline resins, amino resins, polyamine compounds, polyamide resins and glyoxals are preferred in view of developability and printing properties.

Examples of the amino resins include a commonly known melamine resin, a urea resin, a benzoguanamine resin, a glycoluryl resin and modified resins thereof such as a carboxy-modified melamine resin and so forth. Further, in order to accelerate crosslinking reaction, tertiary amines may be used in combination in the case of employing the foregoing glycidyl compound, and an acidic compound such as a p-toluenesulfonic acid, a dodecylbenzenesulfonic acid or an ammonium chloride may be used in combination in the case of employing an amino resin. When a light sensitive composition is heated through heated air, a heated roller or a laser, these crosslinking agents in the composition are reacted with a compound containing a nonionic hydrophilic group of at least 30% by weight to crosslink the compound.

Examples of the polymeric compound containing at least 30% by weight of a nonionic hydrophilic group will be listed below.

1. Vinyl pyrrolidone-vinyl acetate copolymer (60/40) with a weight average molecular-weight of 34000

Product name: Luviskol 64 produced by BASF Japan, VP/VA=60% by weight/40% by weight copolymer

2. Vinyl pyrrolidone-l-butene copolymer (90/10) weight with a weight average molecular weight of 17000

Product name: GANEX P-904 LC ISP Chemicals

3. Vinyl pyrrolidone-glycidyl methacrylate copolymer (70/30) with a weight average molecular weight of 10000

4. Polyacrylamide with a weight average molecular weight of 1700

Product name: Acoflock N104 produced by Mitsui Chemicals AquaPolymer, Inc.

### (Polymerizable Ethylenically Unsaturated Compound)

The polymerizable ethylenically unsaturated compound in the invention (hereinafter also referred to as ethylenically unsaturated compound) is a compound having in the molecule a polymerizable ethylenically double bond. As the ethylenically unsaturated compound, there are known monomers such as a conventional radically polymerizable monomer and a polyfunctional monomer or oligomer having two or more of an ethylenic double bond in the molecule generally used in a conventional ultraviolet curable resin composition.

These ethylenically unsaturated compounds are not specifically limited. Typical examples thereof include a monofunctional acrylate such as 2-ethylhexyl acrylate, 2-hydroxypropyl acrylate, glycerol acrylate, tetrahydrofurfuryl acrylate, phenoxyethyl acrylate, nonylphenoxyethyl acrylate, tetrahydrofurfuryl-oxyethyl acrylate, tetrahydrofurfuryloxyhexanorideacrylate, an ester of 1,3-dioxane-ε-caprolactone adduct with acrylic acid, or 1,3-dioxolane acrylate; a methacrylate, itaconate, crotonate or maleate alternative of the above acrylate; a bifunctional acrylate such as ethyleneglycol diacrylate, triethyleneglycol diacrylate, pentaerythritol diacrylate, hydroquinone diacrylate, resorcin diacrylate, hexanediol diacrylate, neopentyl glycol diacrylate, tripropylene glycol diacrylate, hydroxypivalic acid neopentyl glycol diacrylate, neopentyl glycol adipate diacrylate, diacrylate of hydroxypivalic acid neopentyl glycol-ε-caprolactone adduct, 2-(2-hydroxy-1,1-dimethylethyl)-5-hydroxymethyl-5-ethyl-1,3-dioxane diacrylate, tricyclodecanedimethylol acrylate, tricyclodecanedimethylol acrylate-ε-caprolactone adduct or 1,6-hexanediol diglycidylether diacrylate; a dimethacrylate, diitaconate, dicrotonate or dimaleate alternative of the above diacrylate; a polyfunctional acrylate such as trimethylolpropane triacrylate, ditrimethylolpropane tetraacrylate, trimethylolethane triacrylate, pentaerythritol triacrylate, pentaerythritol tetraacrylate, dipentaerythritol tetraacrylate, dipentaerythritol pentaacrylate, dipentaerythritol hexacrylate, dipentaerythritol hexacrylate-ε-caprolactone adduct, pyrrogallol triacrylate, propionic acid dipentaerythritol triacrylate, propionic acid dipentaerythritol tetraacrylate or hydroxypivalylaldehyde modified dimethylolpropane triacrylate; a methacrylate, itaconate, crotonate or maleate alternative of the above polyfunctional acrylate.

### (Polymerizable Ethylenically Unsaturated Compound Containing a Light Oxidizable Group)

The polymerizable ethylenically unsaturated compound used in the image formation layer is preferably a polymerizable ethylenically unsaturated compound containing at least a light oxidizable group.

An addition-polymerizable compound containing both light oxidizable group and urethane group is especially preferred. Examples of the light oxidizable group include a thio group, a thioether group, a ureido group, an amino group, and an enol group, each of which may be a member constituting heterocycles. As moieties containing these groups, there are, for example, a triethanolamino moiety, a triphenylamino moiety, a thioureide moiety an imidazolyl moiety, an oxazolyl moiety, a thiazolyl moiety, an acetylacetonyl moiety, an N-phenylglycine moiety, and an ascorbic acid moiety. Preferred is an addition-polymerizable compound containing a tertiary amino group or a thioether group.

Exemplified compounds containing a light oxidizable group are listed in European Patent Publication Nos. 287,818, 353,389 and 364,735. Among the exemplified compounds, compounds containing a tertiary amino group, and a ureido group and/or a urethane group are preferred.

Examples of the compound containing both light oxidizable group and urethane group are listed in Japanese Patent Publication No. 2669849, and Japanese Patent O.P.I. Publication Nos. 63-260909, 6-35189 and 2001-125255.

A reaction product of a polyhydric alcohol having a tertiary amino group in the molecule, a diisocyanate and a compound having a hydroxyl group and an addition polymerizable ethylenically double bond in the molecule is preferably used in the invention.

Examples of the polyhydric alcohol having a tertiary amino group in the molecule include triethanolamine, N-methyldiethanolamine, N-ethyldiethanolamine, N-ethyldiethanolamine, N-n-butyldiethanolamine, N-tert-butyldiethanolamine, N,N-di(hydroxyethyl)aniline, N,N, N′, N′-tetra-2-hydroxypropylethylenediamine, p-tolyldiethanolamine, N,N, N′, N-tetra-2-hydroxyethylethylenediamine, N,N-bis(2-hydroxypropyl)aniline, allyldiethanolamine, 3-dimethylamino-1,2-propane diol, 3-diethylamino-1,2-propane diol, N,N-di(n-propylamino)-2,3-propane diol, N,N-di(iso-propylamino)-2,3-propane diol, and 3-(N-methyl-N-benzylamino)-1,2-propane diol, but the invention is not specifically limited thereto.

Examples of the diisocyanate include butane-1,4-diisocyanate, hexane-1,6-diisocyanate, 2-methylpentane-1,5-diisocyanate, octane-1,8-diisocyanate, 1,3-diisocyanatomethylcyclohexanone, 2,2,4-trimethylhexane-1,6-diisocyanate, isophorone diisocyanate, 1,2-phenylene diisocyanate, 1,3-phenylene diisocyanate, 1,4-phenylene diisocyanate, tolylene-2,4-diisocyanate, tolylene-2,5-diisocyanate, tolylene-2,6-diisocyanate, 1,3-di(isocyanatomethyl)benzene, and 1,3-bis(1-isocyanato-1-methylethyl)benzene, but the invention is not specifically limited thereto. Examples of the compound having a hydroxyl group and an addition polymerizable ethylenically double bond in the molecule include 2-hydroxyethyl methacrylate (MH-1), 2-hydroxyethyl acrylate (MH-2), 4-hydroxybutyl acrylate (MH-4), 2-hydroxypropylene-1,3-dimethacrylate (MH-7), and 2-hydroxypropylene-1-methacrylate-3-acrylate (MH-8).

The reaction product above can be synthesized according to the same method as a conventional method in which a urethaneacrylate compound is ordinarily synthesized employing an ordinary diol, a diisocyanate and an acrylate having a hydroxyl group.

Examples of the reaction product of a polyhydric alcohol having a tertiary amino group in the molecule, a diisocyanate and a compound having a hydroxyl group and an addition polymerizable ethylenically double bond in the molecule will be listed below.
M-1: A reaction product of triethanolamine (1 mole), hexane-1,6-diisocyanate (3 moles), and 2-hydroxyethyl methacrylate (3 moles)
M-2: A reaction product of triethanolamine (1 mole), isophorone diisocyanate (3 moles), and 2-hydroxyethyl methacrylate (3 moles)
M-3: A reaction product of N-n-butyldiethanolamine (1 mole), 1,3-bis(1-cyanato-1-methylethyl)benzene (2 moles), and 2-hydroxypropylene-1-methacrylate-3-acrylate (2 moles)
M-4: A reaction product of N-n-butyldiethanolamine (1 mole), 1,3-di(cyanatomethyl)benzene (2 moles), and 2-hydroxypropylene-1-methacrylate-3-acrylate (2 moles)
M-5: A reaction product of N-methydiethanolamine (1 mole), tolylene-2,4-diisocyanate (2 moles), and 2-hydroxypropylene-1,3-dimethacrylate (2 moles)

### <Other Polymerizable Ethylenically Unsaturated Compound>

As the polymerizable ethylenically unsaturated compound, a prepolymer can be used.

A prepolymer can be used, and examples of the prepolymer include compounds as described later. A prepolymer with a photopolymerizable property, which is obtained by incorporating acrylic acid or methacrylic in an oligomer with an appropriate molecular weight, can be suitably employed.

These prepolymers can be used singly, in combination or as their mixture with the above described monomers and/or oligomers.

Examples of the prepolymer include polyester (meth)acrylate obtained by incorporating (meth)acrylic acid in a polyester of a polybasic acid such as adipic acid, trimellitic acid, maleic acid, phthalic acid, terephthalic acid, hymic acid, malonic acid, succinic acid, glutaric acid, itaconic acid, pyromellitic acid, fumalic acid, pimelic acid, sebatic acid, dodecanic acid or tetrahydrophthalic acid with a polyol such as ethylene glycol, ethylene glycol, diethylene glycol, propylene oxide, 1,4-butane diol, triethylene glycol, tetraethylene glycol, polyethylene glycol, grycerin, trimethylol propane, pentaerythritol, sorbitol, 1,6-hexanediol or 1,2,6-hexanetriol; an epoxyacrylate such as bisphenol A.epichlorhydrin.(meth)acrylic acid or phenol novolak.epichlorhydrin.(meth)acrylic acid obtained by incorporating (meth)acrylic acid in an epoxy resin; an urethaneacrylate such as ethylene glycol.adipic acid.tolylenediisocyanate.2-hydroxyethylacrylate, polyethylene glycol.tolylenediisocyanate.2-hydroxyethylacrylate, hydroxyethylphthalyl methacrylate.xylenediisocyanate, 1,2-polybutadieneglycol.tolylenediisocyanat.2-hydroxyethylacrylate or trimethylolpropane.propylene glycol.tolylenediisocyanate.2-hydroxyethylacrylate, obtained by incorporating (meth)acrylic acid in an urethane resin; a silicone acrylate such as polysiloxane acrylate, or polysiloxane.diisocyanate.2-hydroxyethylacrylate; an alkyd modified acrylate obtained by incorporating a methacroyl group in an oil modified alkyd resin; and a spiran resin acrylate.

The light sensitive layer in the invention may contain a monomer such as a phosphazene monomer, triethylene glycol, an EC modified isocyanuric acid diacrylate, an EO modified isocyanuric acid triacrylate, dimethyloltricyclodecane diacrylate, trimethylolpropane acrylate benzoate, an alkylene glycol acrylate, or a urethane modified acrylate, or an addition polymerizable oligomer or prepolymer having a structural unit derived from the above monomer.

Besides the above compounds, compounds disclosed in Japanese Patent O.P.I. Publication Nos. 58-212994, 61-6649, 62-46688, 62-48589, 62-173295, 62-187092, 63-67189, and 1-244891, compounds described on pages 286 to 294 of “11290 Chemical Compounds” edited by Kagakukogyo Nipposha, and compounds described on pages 11 to 65 of “UV.EB Koka Handbook (Materials)” edited by Kobunshi Kankokai can be suitably used.

The content of the ethylenically unsaturated compound in the image formation layer is preferably from 1.0 to 80% by weight, and more preferably from 3.0 to 70% by weight.

### (Sensitizing Dye)

The image formation layer in the invention is characterized in that it contains a sensitizing dye represented by formula (1) or (2).

In formula (1), R′ through R¹⁴ independently represent a hydrogen atom, an alkyl group, an alkoxy group, a cyano group or a halogen atom, provided that at least one of R¹ through R¹⁰ represents an alkoxy group having a carbon atom number of not less than 1.

It is preferred that R¹, R⁵, R⁶, and R¹⁰ through R¹⁴ independently represent a hydrogen atom, a fluorine atom or a chlorine atom. R¹, R⁵, R⁶, and R¹⁰ are preferably hydrogen atoms. It is preferred that R² through R⁴ and R⁷ through R⁹ independently represent an alkoxy group. At least two of the alkoxy group preferably have a branched alkyl group with a carbon atom number of from 3 to 15. It is preferred that R², R⁴, R⁷ and R⁹ are methoxy groups, and the alkoxy group of R³ and R⁸ has a branched alkyl group with a carbon atom number of from 3 to 15.

In formula (2), R¹⁵ through R³² independently represent a hydrogen atom, an alkyl group, an alkoxy group, a cyano group or a halogen atom, provided that at least one of R¹⁵ through R²⁴ represents an alkoxy group having a carbon atom number of not less than 1.

It is preferred that R¹⁵, R¹⁹, R²⁰, R²⁴ and R²⁵ through R³² independently represent a hydrogen atom, a fluorine atom or a chlorine atom. R¹⁵, R¹⁹, R²⁰ and R²⁴ are preferably hydrogen atoms. It is preferred that R¹⁶ through R¹⁸ and R²¹ through R²³ independently represent an alkoxy group. At least two of the alkoxy group preferably have a branched alkyl group with a carbon atom number of from 3 to 15. It is preferred that R¹⁶, R¹⁸, R²¹ and R²³ are methoxy groups, and the alkoxy group of R¹⁷ and R²² has a branched alkyl group with a carbon atom number of from 3 to 15.

Examples of the compound represented by formula (1) or (2) will be listed below.

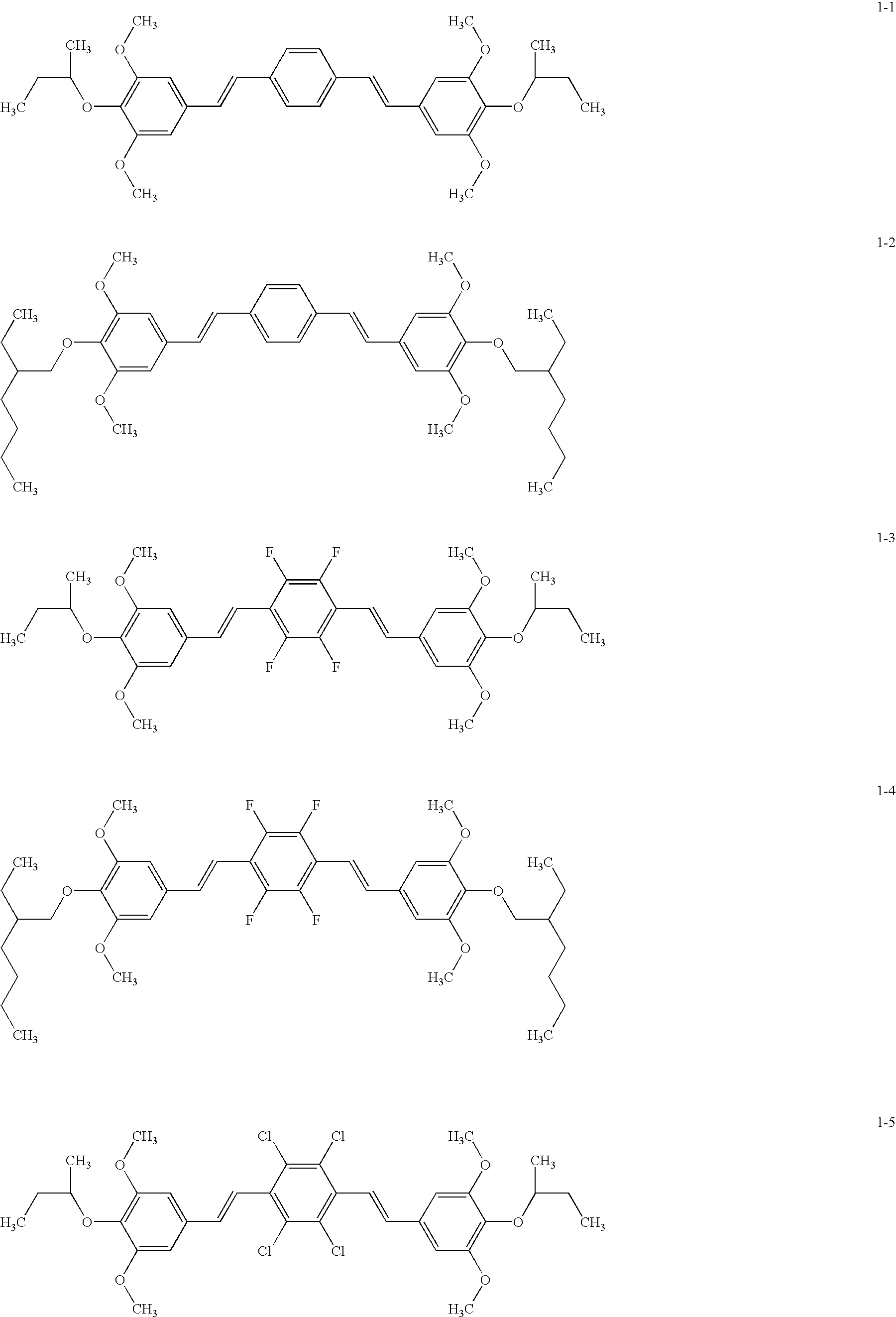

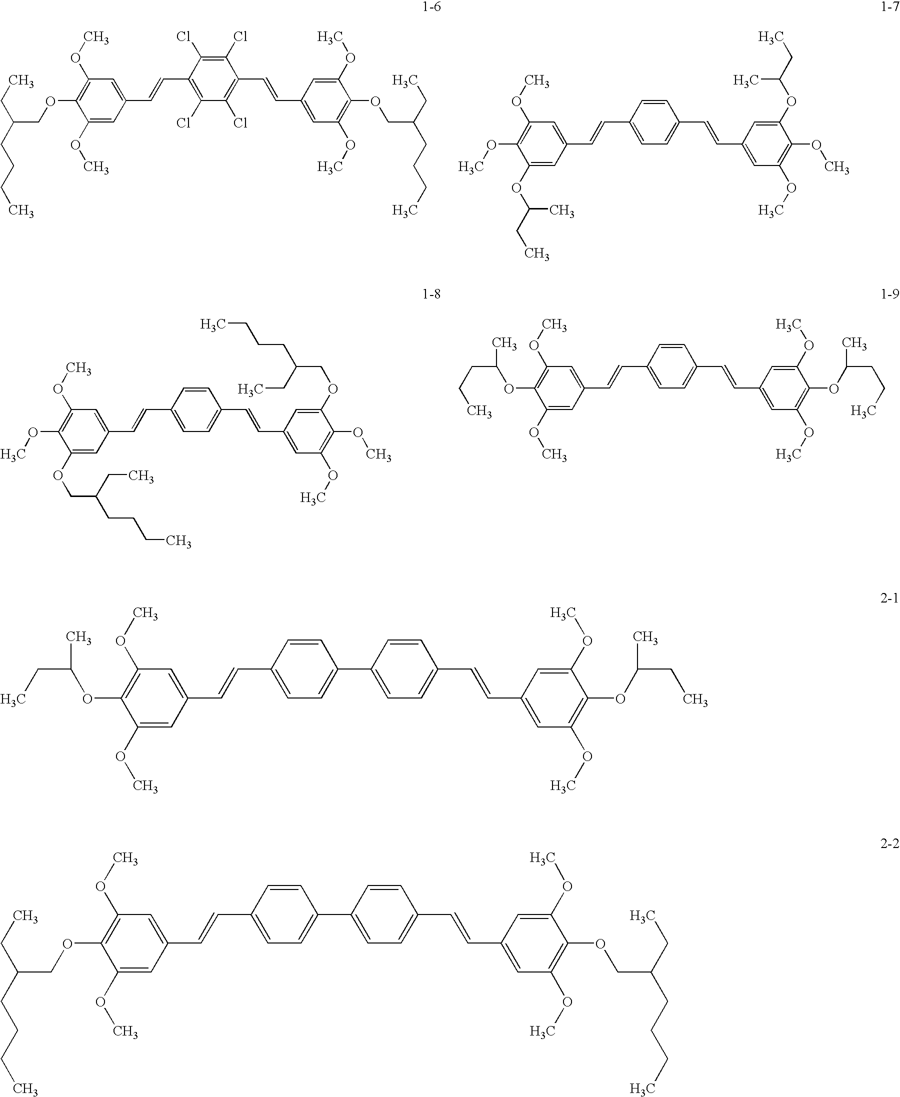

Synthetic example of Sensitizing dye 1 will be shown below.

The synthetic scheme is as follows:

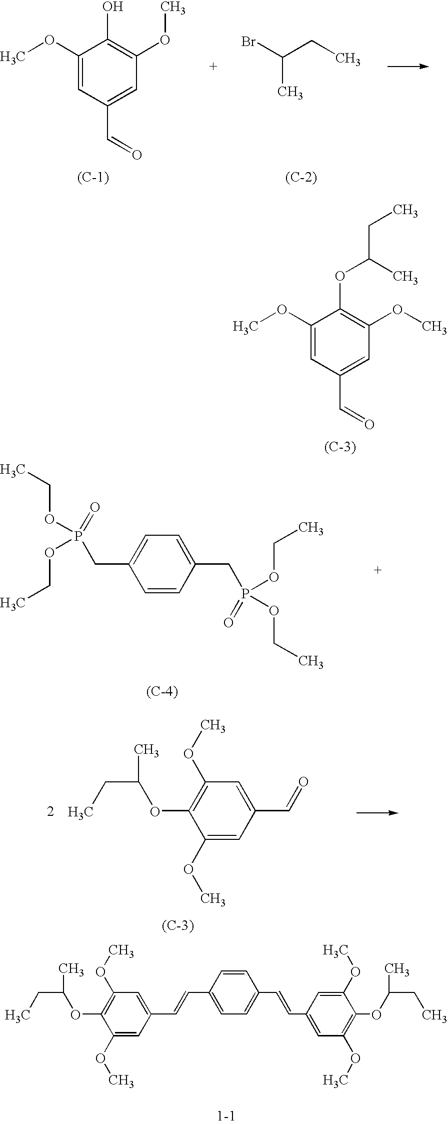

Into 20.25 liter of sulfolane (tetrahydrothiophene-1,1-dioxide) are added 8.365 kg (45.0 mol) of (C-1) and 1.494 kg (9.0 mol) of KI. The resulting mixture was heated to 30° C. under nitrogen atmosphere, added with 3.12 kg (47.25 mol) of KOH and 2.80 kg (20.35 mol) of K₂CO₃, further heated to 75 ° C., and added with 12.78 kg (90.0 mol) of (C-2) over 30 minutes. The resulting mixture was reacted at 75° C. for additional 24 hours, and then cooled to 25 ° C. The reaction mixture was added with 25 liter of water and extracted with 18 liter of methyl tert-butyl ether. The organic phase was washed with 60 liter of a 7.5% by weight K₂CO₃ solution twice, then with 13.5 liter of pure water twice, and finally with 4.5 liter of a 20% by weight NaCl solution twice. The solvent of the resulting organic phase was removed to obtain 7.845 kg of crude intermediate compound (C-3) (yield 75%). The intermediate compound (C-3) was a yellow oily compound and was used in the successive reaction without being purified.

Into 20 liter of THF were added 9.63 kg (25.46 mol) of C-4 and 12.13 kg (50.92 mol) of C-3. The resulting solution was added with 4.70 kg (71.3 mol) of KOH at room temperature, and refluxed for 3.5 hours while heating. After that, the resulting solution was added with 25.2 kg of methanol and 9.9 kg of water, and cooled to 20° C. to obtain precipitate. The resulting precipitate was filtered off, washed with methanol/water several times, and dried at 50° C. to obtain 9.05 kg of sensitizing dye 1-1 with a melting point of 154° C. (yield: 0.67%).

Other sensitizing dyes can be synthesized in the same manner as above.

In addition to the sensitizing dye above, the sensitizing dyes, which are disclosed in for example, Japanese Patent O.P.I. Publication Nos. 2000-98605, 2000-147763, 2000-206690, 2000-258910, 2000-309724, 2001-04254, 2002-202598, 2000-221790, 2003-206307 and 2003-221517 can be used in combination.

The content of the sensitizing dye represented by formula (1) or (2) is preferably 0.1 to 10.0% by weight, and more preferably 3.0 to 7.0% by weight, based on the total solid content of image formation layer.

(Colorant) The image formation layer in the invention can contain a colorant. As the colorant can be used known materials including commercially available materials. Examples of the colorant include those described in revised edition “Ganryo Binran”, edited by Nippon Ganryo Gijutu Kyoukai (publishe by Seibunndou Sinkosha), or “Color Index Binran”. Pigment is preferred.

Kinds of the pigment include black pigment, yellow pigment, red pigment, brown pigment, violet pigment, blue pigment, green pigment, fluorescent pigment, and metal powder pigment. Examples of the pigment include inorganic pigment (such as titanium dioxide, carbon black, graphite, zinc oxide, Prussian blue, cadmium sulfide, iron oxide, or chromate of lead, zinc, barium or calcium); and organic pigment (such as azo pigment, thioindigo pigment, anthraquinone pigment, anthanthrone pigment, triphenedioxazine pigment, vat dye pigment, phthalocyanine pigment or its derivative, or quinacridone pigment). Among these, copper-free phthalocyanine is preferred.

Among these pigment, pigment is preferably used which does not substantially have absorption in the absorption wavelength regions of a spectral sensitizing dye used according to a laser for exposure. The absorption of the pigment used is not more than 0.05, obtained from the reflection spectrum of the pigment measured employing an integrating sphere and employing light with the wavelength of the laser used.

The pigment content is preferably 0.1 to 109 by weight, and more preferably 0.2 to 5% by weight, based on the total solid content of image formation layer.

### (Plasticizer)

The image formation layer can contain a plasticizer in order to improve its adhesion to a support.

Examples of the plasticizer include dimethyl phthalate, diethyl phthalate, dibutyl phthalate, diheptyl phthalate, di-2-ethylhexyl phthalate, di-n-octyl phthalate, didodecyl phthalate, diisodecyl phthalate, butylbenzyl phthalate, diisononyl phthalate, ethylphthalyl ethyl glycol, dimethyl isophthalate, triethylene glycol dicaprylate, dimethyl glycol phthalate, tricresyl phosphate, dioctyl adipate, dibutyl sebacate, and triacetyl glycerin. The plasticizer content of the image formation layer is preferably 0 to 3% by weight, and more preferably from 0.1 to 2% by weight.

A coating liquid for an image formation layer can contain a coatability improving agent such as a surfactant, as long as performance of the invention is not jeopardized. The coatability improving agent is preferably a fluorine-contained surfactant.

Further, in order to improve physical properties of the cured layer, the layer can contain an inorganic filler or a plasticizer such as dioctyl phthalate, dimethyl phthalate or tricresyl phosphate. The content of such a material is preferably not more than 10% by weight, based on the total solid content of the layer.

### (Coating)

The image formation layer in the invention is formed on a support by coating on the support a coating solution containing components contained in the image formation layer.

The solvents used in the preparation of the coating solution for the light sensitive layer in the invention include an alcohol such as sec-butanol, isobutanol, n-hexanol, benzyl alcohol, diethylene glycol, triethylene glycol, tetraethylene glycol or 1,5-pentanediol; an ether such as propylene glycol monobutyl ether, dipropylene glycol monomethyl ether or tripropylene glycol monomethyl ether; a ketone or aldehyde such as diacetone alcohol, cyclohexanone or methyl cyclohexanone; and an ester such as ethyl lactate, butyl lactate, diethyl oxalate or methyl benzoate.

Examples of the coating method include an air doctor coating method, a blade coating method, a wire bar coating method, a knife coating method, a dip coating method, a reverse roll coating method, a gravure coating method, a cast coating method, a curtain coating method, and an extrusion coating method.

### Protective Layer (Oxygen Shielding Layer)

In the invention, an oxygen shielding layer (protective layer) is provided on the image formation layer.

It is preferred in the invention that the protective layer contains a light-to-heat conversion material as described above in view of printing durability and image reproduction.

The light-to-heat conversion material content of the protective layer is preferably from 0.5 to 90% by weight, and more preferably from 1 to 70% by weight.

Preferred materials constituting the protective layer include polyvinyl alcohol, polysaccharide, polyvinyl pyrrolidone, polyethylene glycol, gelatin, glue, casein, hydroxyethyl cellulose, carboxymethyl cellulose, methyl cellulose, hydroxyethyl starch, gum arabic, sucrose octacetate, ammonium alginate, sodium alginate, polyvinyl amine, polyethylene oxide, polystyrene sulfonic acid, polyacrylic acid and a water soluble polyamide. These materials can be used singly or as an admixture of two or more kinds thereof. Polyvinyl alcohol is especially preferred as a material constituting the protective layer.

A protective layer coating solution is obtained by dissolving components as described above in an appropriate solvent. The protective layer is formed, coating on the image formation layer in the invention the protective layer coating solution. The coating amount of the protective layer is preferably 0.1 to 5.0 g/m², and more preferably 0.5 to 3.0 g/m². The protective layer can further contain a surfactant or a matting agent.

The coating method for the protective layer is the same as that for the image formation layer described above. The drying temperature in the protective layer is preferably lower than that in the image formation layer, in which the difference in drying temperature between the protective layer and image formation layer is preferably 10° C. or more, and more preferably 20° C. or more, and the difference is at maximum 50° C.

The drying temperature in the protective layer is preferably lower than the glass transition point (Tg) of the polymeric binder contained in the image formation layer, in which the difference between drying temperature of the protective layer and the glass transition point (Tg) of the polymeric binder contained in the image formation layer is preferably 20° C. or more, and more preferably 40° C. or more, and the difference is at maximum 50° C.

### (Preparation of Printing Plate)

The method of the invention for preparing a printing plate is characterized in that it comprises the steps of imagewise exposing the light sensitive printing plate material as described above, and developing the exposed light sensitive printing plate material with an aqueous solution (hereinafter also referred to as the aqueous solution in the invention) having a pH of from 3 to 9 to remove an image formation layer at unexposed portions, the aqueous solution containing compound A, compound A′, compound B, compound B′ or a compound represented by formula (3) each being described above.

It is preferred that the above process of the invention further comprises, between the exposing and developing steps as described above, the steps of preheating the exposed light sensitive printing plate material, and pre-washing the preheated material with the aqueous solution in the invention to remove the oxygen shielding layer.

### <<Exposure>>

The exposure in the invention is preferably carried out employing laser light. The emission wavelength of the laser light is preferably from a 350 to 450 nm.

The laser light having an emission wavelength of 350 to 450 nm is a laser emitted from a laser capable of stably emitting 350 to 450 nm. Examples of the laser include a combination of a guiding wavelength conversion element, and AlGaAs, InGaAs semiconductor (380 to 450 nm), a combination of a guiding wavelength conversion element, and AlGaInP, InGaAs semiconductor (300 to 350 nm), AlGaInN (350 to 450 nm), and a pulse laser such as an N₂ laser (337 nm, pulse: 0.1 to 10 mJ) or an XeF laser (351 nm, pulse: 10 to 250 mJ).

In the invention, an AlGaInN semiconductor laser (an InGaN type semiconductor laser available on the market, 400 to 410 nm) is preferably used in view of wavelength characteristics.

The total output power of laser used is preferably from 35 to 200 mW, and more preferably from 50 to 180 mW. A single laser or plural lasers can be used. When plural lasers are used, the output power is the total output power of the plural lasers.

A laser scanning method by means of a laser beam includes a method of scanning on an outer surface of a cylinder, a method of scanning on an inner surface of a cylinder and a method of scanning on a plane. In the method of scanning on an outer surface of a cylinder, laser beam exposure is conducted while a drum around which a light sensitive printing plate material (hereinafter also referred to as recording material) is wound is rotated, in which main scanning is carried out by the rotation of the drum, while sub-scanning is carried out by the movement of the laser beam.

In the method of scanning on an inner surface of a cylinder, a recording material is fixed on the inner surface of a drum, a laser beam is emitted from the inside, and main scanning is carried out in the circumferential direction by rotating a part of or an entire part of an optical system, while sub-scanning is carried out in the axial direction by moving straight a part of or an entire part of the optical system in parallel with a shaft of the drum. In the method of scanning on a plane, main scanning by means of a laser beam is carried out through a combination of a polygon mirror, a galvano mirror and an Fθ lens, and sub-scanning is carried out by moving a recording material.

Imagewise exposure is carried out employing an image exposure apparatus having a laser source emitting laser light for imagewise exposure.

### <<Pre-Heating Treatment>>

In the process in the invention of preparing a printing plate, a light sensitive printing plate material is imagewise exposed and subjected to development. Before development, pre-heating treatment is preferably carried out.

It is preferred in the preheating treatment that a light sensitive printing plate material is heated in a given period in hot air circulated and maintained at a constant temperature, wherein the light sensitive printing plate material is uniformly heated.

### <<Oxygen shielding layer removing treatment (Pre-washing treatment)>>

The light sensitive printing plate material of the invention can be pre-washed before development to remove the oxygen shielding layer. Water is generally used as liquid for pre-washing treatment, and the liquid for pre-washing treatment is preferably the same as the aqueous solution in the invention used in the development as described above.

### <<Development>>

The development in the invention is chemical-free development, in which environmental load is greatly reduced as compared with a conventional development. In the conventional development, a conventional alkali aqueous solution is used which contains an inorganic alkali agent such as sodium silicate, potassium silicate, ammonium silicate, sodium secondary phosphate, potassium secondary phosphate, ammonium secondary phosphate; sodium hydrogen carbonate, potassium hydrogen carbonate, ammonium hydrogen carbonate, sodium carbonate, potassium carbonate, ammonium carbonate, sodium borate, potassium borate, lithium borate, sodium hydroxide, potassium hydroxide or ammonium hydroxide or an organic alkali agent such as monomethylamine, dimethylamine, trimethylamine, monoethylamine, diethylamine, triethylamine, monoisopropylamine, diisopropylamine, triisopropylamine, n-butylamine, monoethanolamine, diethanolamine, triethanolamine, monoisopropanolamine, diisopropanolamine, ethyleneimine, ethylenediamine or pyridine.

### (Developer)

A developer used in the printing plate preparing process of the invention is an aqueous solution with a pH of from 3 to 9 containing a compound represented by formula (3), compound A, compound A′, compound B or compound B′.

A compound represented by formula (3), compound A, compound A′, compound B and compound B′ will be explained below.

### <Compound represented by formula (3)>

A compound represented by formula (3) is an acetylene-type nonionic surfactant. For example, the surfactant can be synthesized by reacting tetramethyldecyne diol with ethylene oxide. In formula (3), m and n represent the number of moles of ethyleneoxy (EO), and independently represent an integer of 1 or more, preferably from 1 to 50, and more preferably from 2 to 20. As the number of moles of ethyleneoxy (EO) added increases, hydrophilicity of the surfactant increases. Surfinol 420, 440, 465 or 485, in which the added amount (% by weight) of ethyleneoxy is from 20 to 85%, is available from Nisshin Kagaku Co., Ltd.

### (Compound A)

Compound A refers to a nonionic surfactant having in the molecule a hydrophobic group containing no saturated hydrocarbon group.

### (Compound A′)

Compound A′ refers to a nonionic surfactant having in the molecule a hydrophobic group containing a saturated hydrocarbon group, in which the molecular weight of the saturated hydrocarbon group is from more than 0 to 25% of that of the hydrophobic group (the molecular weight ratio R of the saturated hydrocarbon group to the hydrophobic group is from more than 0 to 25%). In this nonionic surfactant, the molecular weight R is preferably from more than 0 to 5%.

### (Compound B)

Compound B refers to an anionic surfactant having in the molecule a polyoxyethylene group and a hydrophobic group containing no saturated hydrocarbon group.

(Compound B′)

Compound B′ refers to an anionic surfactant having in the molecule a polyoxyethylene group and a hydrophobic group containing a saturated hydrocarbon group, in which the molecular weight of the saturated hydrocarbon group is from more than 0 to 25W of that of the hydrophobic group (the molecular weight ratio R of the saturated hydrocarbon group to the hydrophobic group is from more than 0 to 25%). In the anionic surfactant, the molecular weight ratio R is preferably from more than 0 to 5%.

Herein, in the hydrophobic group containing a saturated hydrocarbon group, the molecular weight of the saturated hydrocarbon group refers to the sum of atomic weight of atoms constituting the saturated hydrocarbon group, and the molecular weight of the hydrophobic group refers to the sum of atomic weight of atoms constituting the hydrophobic group.

Generally, a surfactant has in the molecule a hydrophobic group and a hydrophilic group. Examples of the hydrophobic group include a hydrocarbon group such as an alkyl group, an alkenyl group, an alkinyl group, a phenyl group, a naphthyl group, and examples of the hydrophilic group include an ethyleneoxy group, a hydroxyl group and a carboxyl group.

The molecular weight of the hydrophobic group is preferably from 120 to 2000.

The hydrophobic group herein refers to a group (an atomic group) in a molecule which is difficult to form a bond with a water molecule. Hydrophobic property is determined in terms of degree of hydrophobicity. The degree of hydrophobicity herein is represented by methanol wettability. The methanol wettability shows wettability to methanol, and is determined according to the following method. Distilled water of 50 ml is introduced in a 1000 ml measuring cylinder, and 0.2 g of a compound (in the form of particles) having a hydrophobic group is placed on the top surface of the distilled water. After that, methanol is added in the distilled water while stirring, employing a burette whose dropping tip is immersed in the distilled water while stirring. Methanol is slowly added until the compound in the form of particles is entirely wetted with a mixture solvent of distilled water and completely buried in the mixture solvent. When the amount of methanol necessary to completely wet the compound is a (ml), degree of hydrophobicity is represented by the following formula:

Degree of hydrophobicity (%)={a/(a+50)}×100

In the invention, degree of hydrophobicity is preferably from 20 to 95%.

Preferred examples of compounds A (A-1 through A-6), A′ (A-7 through A-9), B (B-1 through B-7) and B′ (B-8 and B-9) will be listed below, but the invention is not limited thereto.

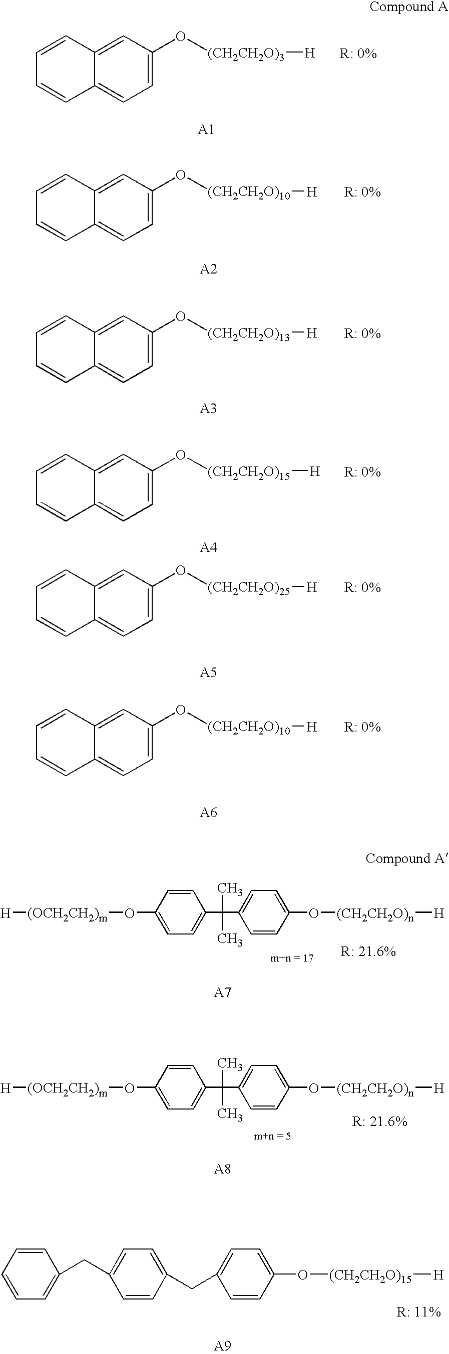

In the above, R represents a molecular weight ratio of the saturated hydrocarbon group in the hydrophobic group to the hydrophobic group.

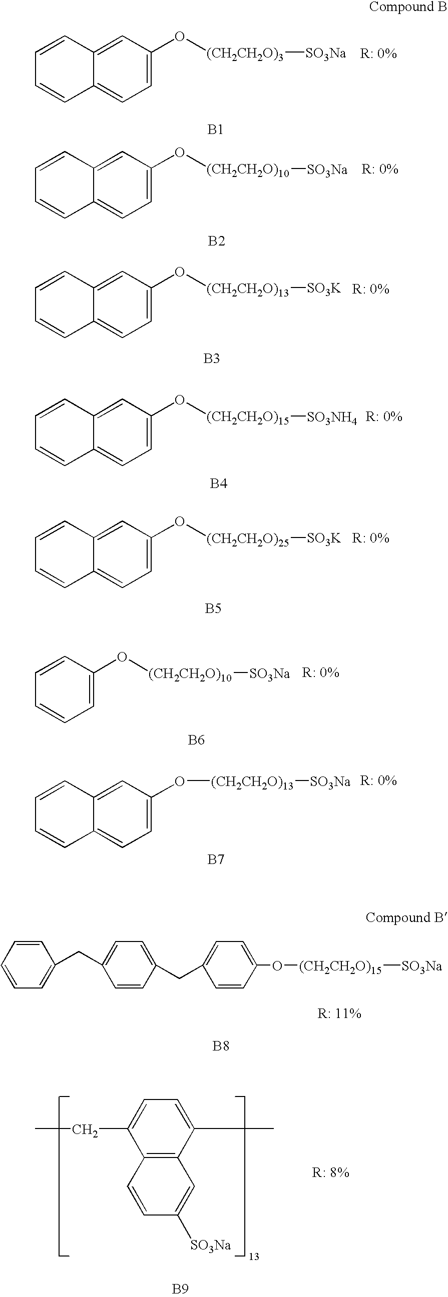

In the above, R represents a molecular weight ratio of the saturated hydrocarbon group in the hydrophobic group to the hydrophobic group.

The developer or its developer replenisher in the invention can further contain an antiseptic agent, a coloring agent, a viscosity increasing agent, an antifoaming agent, or a water softener.

The content of compound A, compound A′, compound B, compound B′ or a compound represented by formula (3) in the aqueous solution in the invention is preferably from 0.1 to 109 by weight, and more preferably from 1 to 5% by weight. When compound A, compound A′, compound B, compound B′ are a compound represented by formula (3) are used as an admixture of two or more kinds thereof in the aqueous solution in the invention, the total content of the admixture is preferably at most 10% by weight.

### (Automatic Developing Machine)

It is advantageous that an automatic developing machine is used in order to develop the light sensitive printing plate material in the invention. It is preferred that the automatic developing machine is equipped with a means for automatically introducing a developer replenisher in a necessary amount into a developing bath, a means for discharging any excessive developer and a means for automatically introducing water in necessary amounts to the developing bath. It is preferred that the automatic developing machine comprises a means for detecting a planographic printing plate material to be transported, a means for calculating the area to be processed of the planographic printing plate material based on the detection, or a means for controlling a replenishing amount of a developer replenisher, a replenishing amount of water to be replenished or replenishing timing based on the detection and calculation. It is also preferred that the automatic developing machine comprises a means for controlling a temperature of a developer, a means for detecting a pH and/or electric conductivity of a developer, or a means for controlling a replenishing amount of the developer replenisher, a replenishing amount of water to be replenished and/or the replenishing timing based on the detected pH and/or electric conductivity. It is also preferred that the automatic developing machine have a function of diluting a developer concentrate with water and a function of stirring the diluted concentrate. Where developing is followed by washing, water used for washing can be reused as a dilution water for diluting the developer concentrate.

The automatic developing machine used in the invention may be provided with a pre-processing section to allow the plate to be immersed in a pre-processing solution prior to development. The pre-processing section is provided preferably with a mechanism of spraying a pre-processing solution onto the plate surface, preferably with a mechanism of controlling the pre-processing solution at a temperature within the range of 25 to 55 ° C., and preferably with a mechanism of rubbing the plate surface with a roller-type brush. Common water and the like are employed as the pre-processing solution.

### Post-Processing

The developed printing plate material is preferably subjected to post-processing. The post-processing step comprises post-processing the developed precursor with a post-processing solution such as washing water, a rinsing solution containing a surfactant, a finisher or a protective gumming solution containing gum arabic or starch derivatives as a main component. The post-processing step is carried out employing an appropriate combination of the post-processing solution described above. For example, a method is preferred in which a developed planographic printing plate precursor is post-washed with washing water, and then processed with a rinsing solution containing a surfactant, or a developed planographic printing plate precursor is post-washed with washing water, and then processed with a finisher, since it reduces fatigue of the rinsing solution or the finisher. It is preferred that a multi-step countercurrent processing is carried out employing a rinsing solution or a finisher.

The post-processing is carried out employing an automatic developing machine having a development section and a post-processing section. In the post-processing step, the developed printing plate is sprayed with the post-processing solution from a spray nozzle or is immersed into the post-processing solution in a post-processing tank. A method is known in which supplies a small amount of water onto the developed printing plate precursor to wash the precursor, and reuses the water used for washing as dilution water for developer concentrate. In the automatic developing machine, a method is applied in which each processing solution is replenished with the respective processing replenisher according to the area of the printing plate precursor to have been processed or the operating time of the machine. A method (use-and-discard method) can be applied in which the developed printing plate material is processed with fresh processing solution and discarded. The thus obtained planographic printing plate is mounted on a printing press, and printing is carried out.

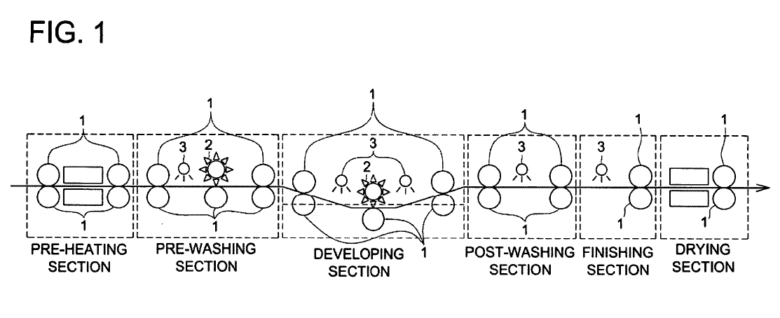

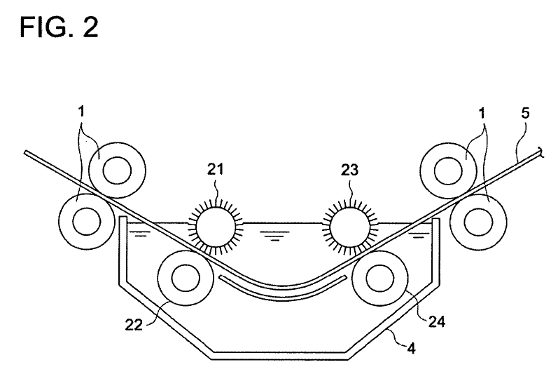

FIG. 1 shows one embodiment of an automatic developing machine used in the invention. The automatic developing machine comprises a pre-heating section, a pre-washing section, a developing section, a post-washing section for removing a residual developer on the printing plate surface, a finishing section and a drying section. The developing section has a structure without a shower as shown in FIG. 2, wherein a printing plate material is only immersed in a developer. In FIG. 1, numerical number 1 shows a transporting roller, numerical number 2 a brush roller, and numerical number 3 a shower.

FIG. 2 shows one embodiment of a developing section of an automatic developing machine used in the invention. An exposed light sensitive printing plate material 5 is developed with the aqueous solution in the invention, while first rotation brush 21 and second rotation brush 23 are brought into contact with the printing plate material surface and rotated by a motor.

The first rotation brush 21 and the second rotation brush 23 are used during development. The first rotation brush 21 preferably has a function mainly for introducing the aqueous solution into an interface between unexposed portions of image formation layer and the support, while the second rotation brush 23 has a function mainly for removing unexposed portions of image formation layer. Each of the first and second rotation brushes may be plural (not illustrated).

The developing section of FIG. 2 comprises a developing tank 4 charged with the aqueous solution in the invention, and the light sensitive printing plate material 5 is passed in the aqueous solution and transported on a transporting path, for example, a guide plate (not illustrated). The first and second brushes 21 and 23 are provided above the transporting path in the aqueous solution of the light sensitive printing plate material 5.

First transporting roller 22 is provided under the first brush 21, and second transporting roller 24 is provided under the second brush 23. The transporting rollers 22 and 24 support the light sensitive printing plate material 5 so that the light sensitive printing plate material surface is rubbed at a given strength with the first and second rotation brushes 21 and 23 rotated.

The light sensitive printing plate material 5 is immersed in the aqueous solution of the developing tank 4 to introduce the aqueous solution into an interface between unexposed portions of image formation layer and the support at a pressure applied by the first rotation brush 21 and the first transporting roller 22, and at the same time, the light sensitive printing plate material surface is rubbed by elastic deformation of the first rotation brush 21 to form an interface between the image formation layer at the unexposed portions and the support whereby the image formation layer on the interface is to be easily removed. Thus, a part of the image formation layer at unexposed portions is removed and the image formation layer at unexposed portions is in a state to be easily removed.

The surface of light sensitive printing plate material 5, which is immersed in the aqueous solution of the developing tank 4, is rubbed with the second rotation brush 23 at a given strength to remove the image formation layer at the unexposed portions on the interface which is to be easily removed, whereby the light sensitive printing plate material is developed so that only the hardened image formation layer remains on the support.

In order to provide to the first rotation brush 21 a function mainly for introducing the aqueous solution into an interface between unexposed portions of image formation layer and the support and to provide to the second rotation 23 a function for removing unexposed portions of image formation layer, there is a method which lowers rigidity of the first rotation brush 21 to the second rotation brush 23, or a method which lowers rotation rate of the first rotation brush 21 to the second rotation brush 23. As the first and second rotation brushes 21 and 23, a channel brush, a pile brush, or a molleton brush can be used.

In the development section as shown in FIG. 2, development can be carried out, sufficiently supplying the aqueous solution in the invention. When light sensitive planographic printing plate material 5 is developed with the aqueous solution in the invention in the developing tank 4 heated to a specific temperature (of from room temperature to a boiling point of the solution) by a heater (not illustrated), the heated aqueous solution permeates an image formation layer at unexposed portions to form an interface between the image formation layer and the support, where the image formation layer is easily removed, whereby proper development can be carried out.

### (Printing)

A planographic printing plate prepared via the printing plate preparing process of the present invention is subjected to printing, but a conventional planographic offset printing press in which dampening water is utilized as described below is usable as a printing press.

Printing paper, printing ink, dampening water and so forth which are used for printing are not specifically limited.

In recent years, printing ink containing no petroleum volatile organic compound (VOC) has been developed and used in view of environmental concern. The present invention provides excellent effects in employing such a printing ink friendly to environment.

As the ink, ink containing soybean oil is preferable.

Generally, the ink containing soybean oil is one mixed with an organic pigment, an inorganic pigment, a binder resin, soybean oil or a high boiling point petroleum solvent, and may also contain a plasticizer, a stabilizer, a desiccant agent, a thickner, a dispersant, a filler or such as an auxiliary substance.

As ink preferably usable for printing, ink accredited via the soy seal recognition system by American Soybean Association (ASA) is provided.

Commonly known soybean oil is usable as the soybean oil, and soybean oil for food (purified soybean oil) accredited by Japan Agri

The ink containing soybean oil is sold by various ink manufacturers, and easily purchased. Examples thereof include Naturalith 100 sheet-fed printing ink and WebWorldAdvan web offset printing ink (produced by Dainippon Ink and Chemicals, Inc.), TK Hyunity SOY sheet-fed printing ink, TK HyEcho-SOY sheet-fed printing ink, CK WINECO-SOY sheet-fed printing ink, WD Super LeoEcoo-SOY web offset printing ink, WD LeoEcoo-SOY web offset printing ink and SCRSOY Business Form ink (produced by Toyo Ink MFG. Co., Ltd.), and Soycelvo sheet-fed printing ink (produced by Tokyo Printing Ink MFG. Co., Ltd.).

### (Dampening Water)

Dampening water generally applied for printing is usable as the dampening water. Dampening water comprised only of water or a dampening water containing additives may be used.

Dampening water containing no isopropanol, which is conventionally used, is preferably used as dampening water. In this case, dampening water not containing isopropanol means one having an isopropanol content of less than 0.5% by weight.

An aqueous solution containing a surfactant is preferably used as the dampening water.

As water for dampening water, water such as tap water or well water or so forth can be utilized.

The dampening water may contain a slight amount of components, such as acids, for example, a phosphoric acid or its salt, a citric acid or its salt, a nitric acid or its salt and an acetic acid or its salt, specifically, phosphoric acid, ammonium phosphate, sodium phosphate, citric acid, ammonium citrate, sodium citrate, acetic acid, ammonium acetate or sodium acetate, or water-soluble polymeric compounds such as carboxymethylcellulose, carboxyethylcellulose and so forth.

The content of these components is less than 0.1% by weight, and preferably less than 0.05% by weight.

Further, the dampening water may contain glycol-based compounds such as propylene glycol monomethylether, propylene glycol monoethylether, propylene glycol monobutylether, propylene glycol propyl ether, propylene glycol dimethyl ether, propylene glycol diethyl ether, propylene glycol dibutyl ether, dipropylene glycol dimethyl ether, dipropylene glycol diethyl ether, dipropylene glycol dibutyl ether and so forth. The content of the glycol-based compound is preferably a small amount of less than 0.1% by weight, and more preferably less than 0.05% by weight.

The dampening water may contain a surfactant.

A nonionic surfactant, an anionic surfactant, a cationic surfactant or a mixture thereof is preferably used as the surfactant.

These surfactants may be used singly or as admixture of two or more kinds thereof. The surfactant content of the dampening water is preferably not more than 0.01% by weight, and more preferably not more than 0.05% by weight.

### EXAMPLES

Next, the present invention will be explained in the following examples, but the present invention is not limited thereto. In the examples, “%” and “parts” represent “% by weight” and “parts by weight”, respectively, unless otherwise specified. <<Preparation of light sensitive printing plate material sample 1>>

### (Preparation of Support)

A 0.3 mm thick aluminum plate (material 1050, quality H16) was degreased at 60° C. for one minute in a 5% sodium hydroxide solution, washed with water, immersed at 25° C. for one minute in 10% sulfuric acid solution to neutralize, and then washed with water. The resulting aluminum plate was electrolytically surface-roughened in a 11 g/liter hydrochloric acid solution at 25° C. for 20 seconds, using an alternating current having a frequency of 50 HZ and a current density of 50 A/dm²₁ washed with water, desmutted in a 1% sodium hydroxide solution at 50° C. for 10 seconds, and neutralized in a 30% sulfuric acid solution at 50° C. for 30 seconds, and washed with water. The desmutted aluminum plate was anodized at 25° C. for 30 seconds at a current density of 30 A/dm² and at a voltage of 25 V in a 30% sulfuric acid solution, washed with water, subjected to hydrophilization treatment at 75° C. for 30 seconds in a 0.44% polyvinyl phosphonic acid solution, washed with distilled water, and dried with cool air. Thus, support having a hydrophilic surface was obtained. The center line average surface roughness (Ra) of the support was 0.50 μm.

The center line average surface roughness Ra is defined according to JIS surface roughness (JIS-B-0601). When a roughness curve is represented by formula Y=f(X) in the coordinates in which the direction of the center line of the curve is set as the X-axis and the longitudinal magnification direction perpendicular to the X-axis is set as the Y-axis, the center line average surface roughness Ra (μm) is represented by the following equation:

$$R a = \frac{1}{L} {\int }_{0}^{L} \vert f ( x ) \vert d x$$

wherein L is a length to be measured.

### (Coating of Image Formation Layer)

The following image formation layer coating solution 1 was coated on the resulting support through a wire bar, and dried at 95° C. or 1.5 minutes give an image formation layer having a coating amount of 1.5 g/m².

(Image formation layer coating solution 1)

| | | |
|---|---|---|
| Ethylenically unsaturated compound M-1 | 25.0 | parts |
| Ethylenically unsaturated compound | 15.0 | parts |
| (NK Ester 4G produced by ShinNakamura Kagaku Co., | | |
| Ltd., polyethylene glycol dimethacrylate) | | |
| Photopolymerization initiator | 3.0 | parts |
| (η-cumene-(η-cyclopentadienyl) iron hexafluorophosphate) | | |
| Photopolymerization initiator (BR-22) | 1.5 | parts |
| Sensitizing dye (1-1) | 4.0 | parts |
| Water-soluble polymeric binder | 40 | parts |
| (Vinyl pyrrolidone-vinyl acetate (60/40 mol %) copolymer | | |
| with a weight average molecular weight of 34,000, | | |
| Rubiskol 64 available from BASF Japan Inc.) | | |
| N-Phenylglycine benzyl ester | 4.0 | parts |
| Copper-free Phthalocyanine pigment dispersion | 6.0 | parts |
| (described below) | | |
| 2-t-Butyl-6-(3-t-butyl-2-hydroxy-5- | 0.5 | parts |
| methylbenzyl)-4-methylphenylacrylate | | |
| (Sumirizer GS: produced by Sumitomo 3M Co., Ltd.) | | |
| Glycol-modified siloxane surfactant | 0.5 | parts |
| (BYK337, produced by BYK CHEMIE Co., Ltd.) | | |
| Methyl ethyl ketone | 10 | parts |

Cyclohexanone was added to make a solution of 1000 parts.

<Copper-free Phthalocyanine pigment dispersion>

| | | |
|---|---|---|
| Copper-free Phthalocyanine pigment (PB16) | 10.0 | parts |
| Fluidizing agent | 0.5 | parts |
| (Solsperse 5000, available from Avecia Co., Ltd.) | | |
| Polymer dispersant | 1.5 | parts |
| (Solsperse 24000GR available from Avecia Co., Ltd.) | | |
| Methyl ethyl ketone | 88.0 | parts |
| (Coating of oxygen shielding layer) | | |

Subsequently, the following oxygen shielding layer coating solution 1 was coated on the resulting image formation layer using an applicator, and dried at 75° C. for 1.5 minutes to form an oxygen shielding layer with a coating amount of 1.1 g/m². Thus, light sensitive printing plate material sample 1 was prepared.

(Oxygen shielding layer coating solution 1)

| | | |
|---|---|---|
| Polyvinyl alcohol (GL-05, produced | 82.5 | parts |
| by Nippon Gosei Kagaku Co., Ltd.) | | |
| Polyvinyl pyrrolidone (K-30, | 12 | parts |
| produced by BASF Inc.) | | |
| Surfactant (Surfinol 465, ethylene oxide | 0.5 | parts |
| addition amount of 65% by weight, 10 mol, available from | | |
| Nisshin Kagaku Co., Ltd.) | | |
| Water | 900 | parts |

### <<Preparation of Light Sensitive Printing Plate Material Samples 2 through 4>>

Light sensitive printing plate material samples 2 through 4 were prepared in the same manner as in light sensitive printing plate material sample 1 above, except that a sensitizing dye as shown in Table 1 was used instead of sensitizing dye 1-1.

### <<Preparation of Printing Plate Sample>>

### (Imagewise Exposure)

Each of the light sensitive printing plate material samples obtained above was imagewise exposed at a resolving degree of 2400 dpi, employing a plate setter News CTP (produced by ECRM Co., Ltd.) equipped with a 405±5 nm light source with an output power of 60 mW). The image pattern used for the exposure comprised 3% square dots with a screen line number of 175 lpi. Herein, dpi represents the dot numbers per 2.54 cm, and lpi represents a line number per inch, i.e., 2.54 cm.

### (Development Treatment)

The resulting exposed sample was processed employing an automatic developing machine (Raptor 85 Polymer produced by Glunz & Jensen Inc.) to obtain a planographic printing plate. The exposed sample was pre-heated at 100° C. for 10 seconds, pre-washed in a pre-washing section to remove the oxygen shielding layer, developed for 20 seconds with the following developers 1 through 4 in a developing section, post-washed in a post-washing section to remove the residual developer, and coated with a gumming solution (GW-3 available from Mitsubishi Kagaku Co., Ltd, diluted by a factor of 2) in a finishing section to protect the printing plate surface. Thus, a printing plate sample was obtained.

<Preparation of developer 1/developer replenisher 1>

| | |
|---|---|
| Surfactant 1 (B8) | 30.0 g/liter |
| Surfactant 2 (Surfinol 465 available from | 10.0 g/liter |
| Nisshin Kagaku Co., Ltd.) | |
| Ethylenediaminetetraacetic acid | 0.5 g/liter |

Water was added to make 1 liter. The pH of developer 1 was 6.8.

### <Preparation of Developer 2/Developer Replenisher 2 through developer 5/developer replenisher 5>

Developer 2/developer replenisher 2 through developer 5/developer replenisher 5 were prepared in the same manner as in developer 1/developer replenisher 1 above, except that surfactants 1 and 2 were changed to surfactants as shown in Table 1.

### <<Evaluation>>

The resulting printing plate samples were evaluated according to the following method.

### (Sensitivity)

The minimum exposure energy (μJ/cm²), at which the 3% dot image was reproduced, was evaluated as a measure of sensitivity.

### (Printing Durability)

The light sensitive printing plate material sample was processed in the same manner as above, except that exposure was carried out at exposure energy of 50 μJ/cm², and a 1 to 99% dot image with a screen line number of 175 lpi was used as the image pattern for the exposure. Thus, printing plate sample was obtained. Printing was carried out employing the printing plate sample, wherein a 2% by weight solution of Astromark 3 (produced by Nikken Kagaku Kenkyusyo Co., Ltd.) was used as dampening water, a soybean oil-type ink, TK Hyecho Soy 1 Magenta), produced by Toyo Ink Manufacturing Co.), as printing ink, and a coated paper as the printing paper.

The number of prints printed till when reduction of 2% dots was visually observed in the prints was evaluated as a measure of printing durability.

### (Background Contamination)

The light sensitive printing plate material samples were stored at 55° C. for three days, and processed in the same manner as carried out in evaluation of printing durability above, except that a fatigue developer obtained after development described later was carried out below was used as a developer. Employing the thus obtained printing plate sample, printing was carried out in the same manner as above. One hundred prints were printed, and contamination at non-image portions of the one hundredth print was visually observed, and evaluated according to the following criteria.
A: No contamination at non-image portions was observed.
B: Slight contamination at non-image portions was observed, but was not practically problematic.
C: Contamination at non-image portions was observed.
D: Apparent contamination at non-image portions was observed.

### <Preparation of Fatigue Developer>

Light sensitive printing plate materials having an area of 1003×800 mm was developed with a developer to obtain an average image area rate of 35%, wherein 50 ml of developer replenisher was replenished in the developer every time one sheet of light sensitive printing plate material was developed. Development of one hundred sheets of light sensitive printing plate material per day was carried out for one month. Development was not carried out at night (PM 5:00 to AM 9:00 of next day) and on Saturday and Sunday.

The results are shown in Table 1.

TABLE 1

| | Sample | | Developer and developer | | | | | | |
|---|---|---|---|---|---|---|---|---|---|
| Process | | Sensitizing | replenisher used | | | | | | |
| No. | No. | dye | No. | Surfactant 1 | Surfactant 2 | (i) | (ii) | (iii) | Remarks |
| 1 | 1 | 1-1 | 1 | B7 | Surfinol 465 | 10 | 200 | A | Inv. |
| 2 | 2 | 1-2 | 1 | B7 | ″ | 10 | 200 | A | Inv. |
| 3 | 3 | 2-1 | 1 | B7 | ″ | 20 | 200 | A | Inv. |
| 4 | 4 | CD | 1 | B7 | ″ | 100 | 50 | C | Comp. |
| 5 | 1 | 1-1 | 2 | B7 | None | 20 | 150 | B | Inv. |
| 6 | 1 | 1-1 | 3 | A1 | None | 20 | 150 | B | Inv. |
| 7 | 1 | 1-1 | 4 | B2 | None | 20 | 150 | B | Inv. |
| 8 | 1 | 1-1 | 5 | CS | None | 60 | 150 | B | Comp. |

Inv.: Inventive,
Comp.: Comparative
(i) Sensitivity (μJ/cm²);
(ii) Printing durability (×1000);
(iii) Background contamination;
CD: Comparative dye 1,7-diethylamino-4-trifluoromethylcumarine;
CS: Comparative surfactant 1, Pronone 204 (EO-PO-EO block polymer, available from Nippon Yushi Co., Ltd.)

As is apparent from Table 1, inventive light sensitive printing plate material samples provide high sensitivity and inventine processes provide high printing durability and minimize background contamination due to a fatigue developer.

What is claimed is:

1. A process of preparing a printing plate comprising the steps of:
(a) imagewise exposing a light sensitive printing plate material comprising a hydrophilic support and provided thereon, an image formation layer and an oxygen shielding layer in that order; and
(b) developing the exposed light sensitive printing plate material with an aqueous solution having a pH of from 3 to 9 to remove an image formation layer at unexposed portions;
wherein the image formation layer contains a photopolymerization initiator (A), a water-soluble polymeric binder (B), a polymerizable ethylenically unsaturated compound (C) and a sensitizing dye (D) represented by formula (1) or (2), 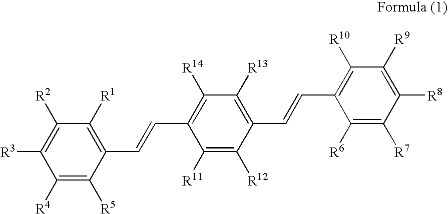
wherein R¹, R², R³, R⁴, R⁵, R⁶, R⁷, R⁸, R⁹, R¹⁰, R¹¹, R¹², R¹³ and R¹⁴ independently represent a hydrogen atom, an alkyl group, an alkoxy group, a cyano group or a halogen atom, provided that at least one of R¹, R², R³, R⁴, R⁵, R⁶, R⁷, R⁸, R⁹ and R¹⁰ represents an alkoxy group having a carbon atom number of not less than 1, 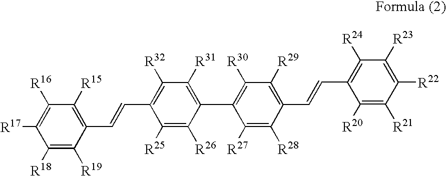
wherein R¹⁵, R¹⁶, R¹⁷, R¹⁸, R¹⁹, R²⁰, R²¹, R²², R²³, R²⁴, R²⁵, R²⁶, R²⁷, R²⁸, R²⁹, R³⁰, R³¹ and R³² independently represent a hydrogen atom, an alkyl group, an alkoxy group, a cyano group or a halogen atom, provided that at least one of R¹⁵, R¹⁶, R¹⁷, R¹⁸, R₁₉, R²⁰, R²¹, R²², R23 and R²⁴ represents an alkoxy group having a carbon atom number of not less than 1, and wherein the aqueous solution contains at least one selected from compound A, compound A′, compound B, compound B′ and a compound represented by formula (3), the compound A being a nonionic surfactant having in the molecule a first hydrophobic group containing no saturated hydrocarbon group, the compound A′ being a nonionic surfactant having in the molecule a second hydrophobic group containing a saturated hydrocarbon group in which the molecular weight ratio of the saturated hydrocarbon group to the second hydrophobic group is from more than 0 to 25%, the compound B being an anionic surfactant having in the molecule a third hydrophobic group containing no saturated hydrocarbon group, and the compound B′ being an anionic surfactant having in the molecule a fourth hydrophobic group containing a saturated hydrocarbon group in which the molecular weight ratio of the saturated hydrocarbon group to the second hydrophobic group is from more than 0 to 25%, 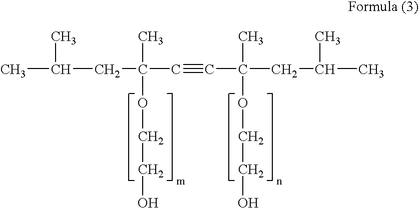
wherein m and n independently represent an integer of 1 or more.

2. The process of claim 1, further comprising, between the exposing and developing steps, the steps of preheating the exposed light sensitive planographic printing plate material, and pre-washing the preheated material with the aqueous solution.

3. The process of claim 1, wherein the exposing is carried out employing a laser.

4. The process of claim 1, wherein the image formation layer further comprises copper-free phthalocyanine as a colorant.

5. A light sensitive printing plate material comprising a hydrophilic support and provided thereon, an image formation layer and an oxygen shielding layer in that order, wherein the image formation layer contains a photopolymerization initiator (A), a water soluble polymeric binder (B), a polymerizable ethylenically unsaturated compound (C) and a sensitizing dye (D) represented by formula (1) or (2), 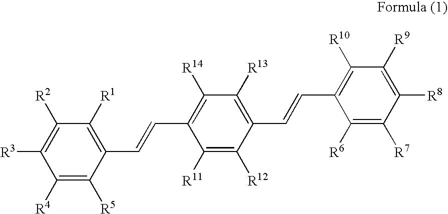
wherein R¹ , R², R³, R⁴, R⁵, R⁶, R⁷, R⁸, R⁹, R¹⁰, R¹¹, R¹², R¹³ and R¹⁴ independently represent a hydrogen atom, an alkyl group, an alkoxy group, a cyano group or a halogen atom, provided that at least one of R¹, R², R³, R⁴, R⁵, R⁶, R⁷, R⁸, R⁹ and R¹⁰ represents an alkoxy group having a carbon atom number of not less than 1, 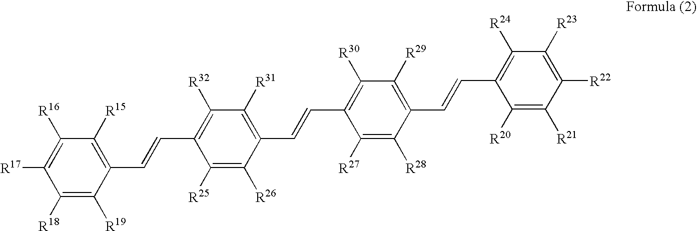
wherein R¹⁵, R¹⁶, R¹⁷, R¹⁸, R¹⁹, R²⁰, R²¹, R²², R²³, R²⁴, R²⁵, R²⁶, R²⁷, R²⁸, R²⁹, R³⁰, R³¹ and R³² independently represent a hydrogen atom, an alkyl group, an alkoxy group, a cyano group or a halogen atom, provided that at least one of R¹⁵, R¹⁶, R¹⁷, R¹⁸, R¹⁹, R²⁰, R²¹, R²², R²³ and R²⁴ represents an alkoxy group having a carbon atom number of not less than 1.

6. The light sensitive printing plate material of claim 5, wherein the image formation layer further comprises copper-free phthalocyanine colorant.
